(19) United States
(12) Patent Application Publication
(10) Pub. No.: US 2026/0165160 A1
(43) Pub. Date: Jun. 11, 2026

(54) THROUGH GLASS VIA LOCAL STRESS REDUCTION

(71) Applicant: Intel Corporation, Santa Clara, CA (US)

(72) Inventors: Hiroki Tanaka, Gilbert, AZ (US); Nanqi Bao, Phoenix, AZ (US); Haobo Chen, Chandler, AZ (US); Brandon Christian Marin, Gilbert, AZ (US); Bai Nie, Chandler, AZ (US); Srinivas Venkata Ramanuja Pietambaram, Chandler, AZ (US); Bohan Shan, Chandler, AZ (US); Robert A. May, Chandler, AZ (US); Jacob Vehonsky, Chandler, AZ (US)

(21) Appl. No.: 18/975,508

(22) Filed: Dec. 10, 2024

(51) Int. Cl. H01L 23/498; H01L 21/48; H01L 23/15

(52) U.S. Cl. CPC H10W 70/635; H10W 70/095; H10W 70/66; H10W 70/692

(57) ABSTRACT

Recesses formed at the tops and bottoms of through glass via (TGV) metal regions during TGV formation can create glass-metal-air triple points. These triple points can be the source of cracks or other damage to a glass layer during thermal treatment in downstream processing due to the coefficient of thermal expansion mismatch between the TGV metal and the glass. To relieve stress at the triple points, the recesses can be filled with a conductive paste or a metal layer formed via electroless plating. Alternatively, during TGV formation, regions of low-modulus dielectric material can be formed where the triple points would otherwise be formed. The low-modulus dielectric material can provide local stress relief and mitigate the formation of glass layer damage in downstream processing.

### BACKGROUND

Glass substrates are a promising alternative to traditional organic substrates (e.g., printed circuit boards) due to their low flatness, and better thermal and mechanical stability, which can enable higher substrate interconnect densities. Through glass vias provide electrical connectivity between a component located on one side of a glass substrate to another component located on the opposite side of the glass substrate.

### BRIEF DESCRIPTION OF THE DRAWINGS

FIGS. 1A-1H are cross-sectional views of a first example structure comprising a glass layer at various stages of manufacture.

FIGS. 2A-2K are cross-sectional views of a second example structure comprising a glass layer at various stages of manufacture.

FIGS. 3A-3K are cross-sectional views of a third example structure comprising a glass layer at various stages of manufacture.

FIGS. 4A-4H are cross-sectional views of a fourth example structure comprising a glass layer at various stages of formation of through glass vias (TGVs) in the structure.

FIG. 5 is a plan view of a fifth example structure comprising a layer of glass comprising through glass vias that have been formed according to any of the embodiments disclosed herein.

FIG. 6 is a first example method of forming through-glass vias.

FIG. 7 is a second example method of forming through-glass vias.

FIG. 8 is a third example method of forming through-glass vias.

FIG. 9 is a third example method of forming through-glass vias.

FIG. 10 is a top view of a wafer and dies that may be included in a microelectronic assembly, in accordance with any of the embodiments disclosed herein.

FIG. 11 is a cross-sectional side view of an integrated circuit device that may be included in a microelectronic assembly, in accordance with any of the embodiments disclosed herein.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

In some existing through glass vias (TGVs) formation processes, etching and polishing of the TGV metal after TGV metal plating can leave TGV regions with top and bottom surfaces that are recessed from top and bottom surfaces of the glass layer within which the TGVs are being formed. These recesses create triple points where the TGV metal, glass, and air meet. Due to the difference in the coefficients of thermal expansion between the TGV metal (typically copper) and the glass layer, downstream thermal treatment (e.g., annealing) causes expansion of the TGV metal along the surface of the glass layer, causing shear stress at the TGV-glass interface. This can cause cracks or other damage in the glass layer. The susceptibility of the glass layer to damage initiated at these triple points can increase at fine TGV pitches.

Disclosed herein are technologies to reduce the amount of stress local to where top and bottom surfaces of TGV metal regions meet a glass layer by filling the recesses at the top and bottom surfaces of the TGV metal regions that can be created after etching and polishing the TGV metal after TGV plating. The recesses are filled with conductive paste or metal plated via an electroless process. The conductive paste can comprise tin, or tin doped with one or more metals. The electroless copper can have grain sizes of less than one micron and the grain sizes of the bulk TGV regions can be in the range of one to ten microns. Alternatively, “lips” comprising low-modulus dielectric material are formed where TGV-glass-air triple points would otherwise be formed. Filling the recesses with conductive paste, doped tin, or forming low-modulus “lips” in place of metal-glass-air triple points can reduce local TGV stress and can alleviate the formation of cracks in the glass layer. This can increase the yield of glass substrates (or cores) that comprise TGVs, thereby reducing the overall cost of manufacturing these components.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, a hole that is described as being substantially filled can contain voids, ends described as being substantially coincident with a surface includes ends that are not exactly flush with the surface but are coincident to within several microns of the surface, and cross-sections that are described as being substantially a particular shape (e.g., quarter circle) includes cross-sections that vary from a perfect version of the particular shape but still have the same general shape as the recited shape.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

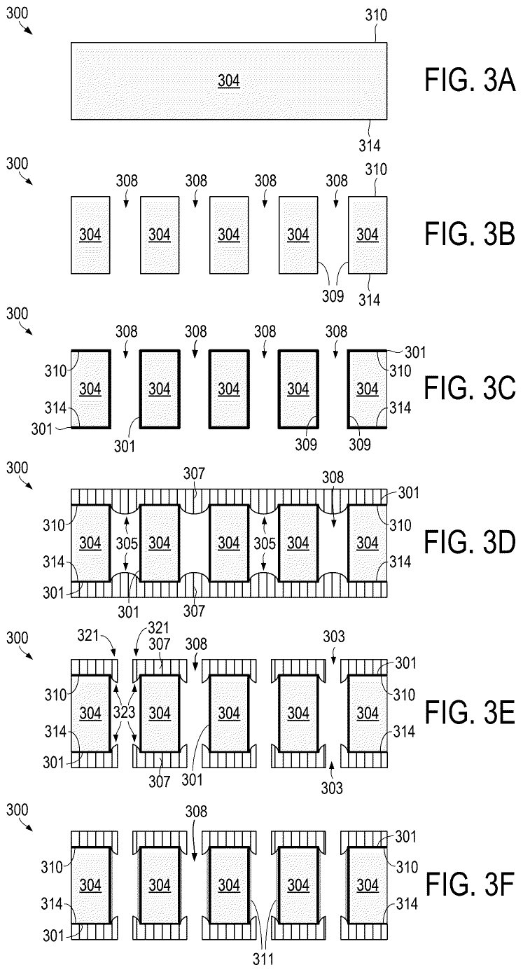

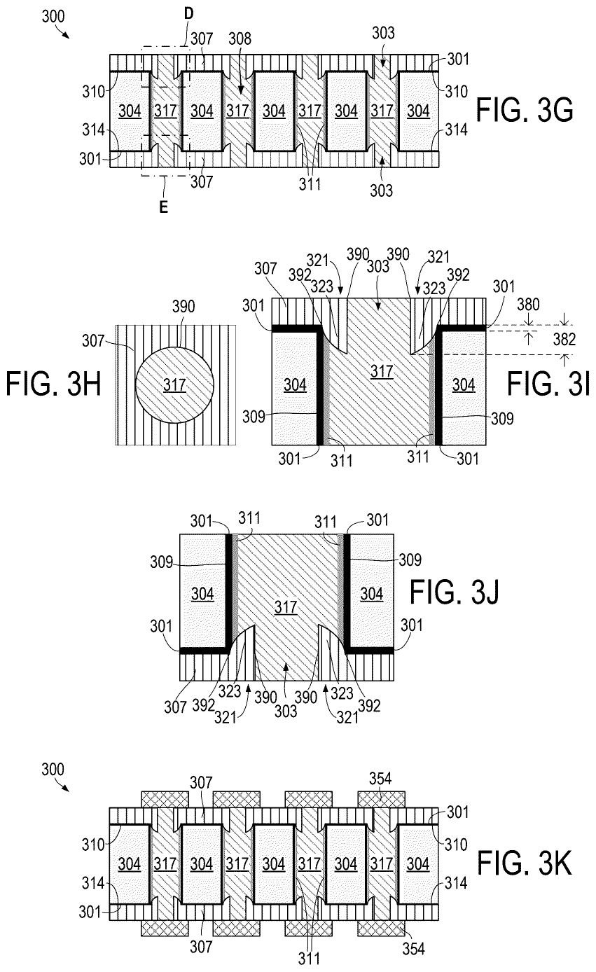

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, with reference to FIG. 3F, the layer 311 is located on a sidewall 309 of the glass layer 304, with an intervening layer 301.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the phrase “electrically coupled” refers to the presence of one or more electrically conductive paths between components that are recited as being electrically coupled.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

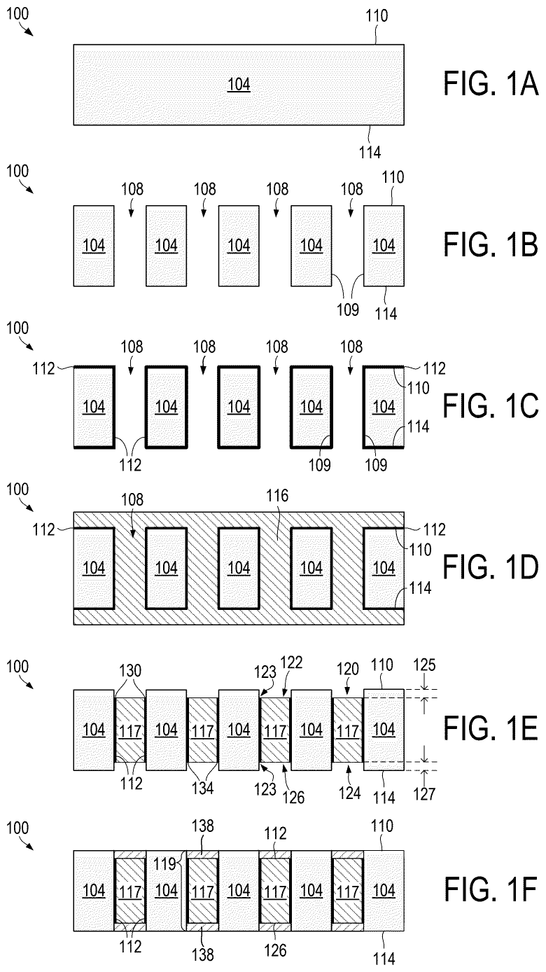

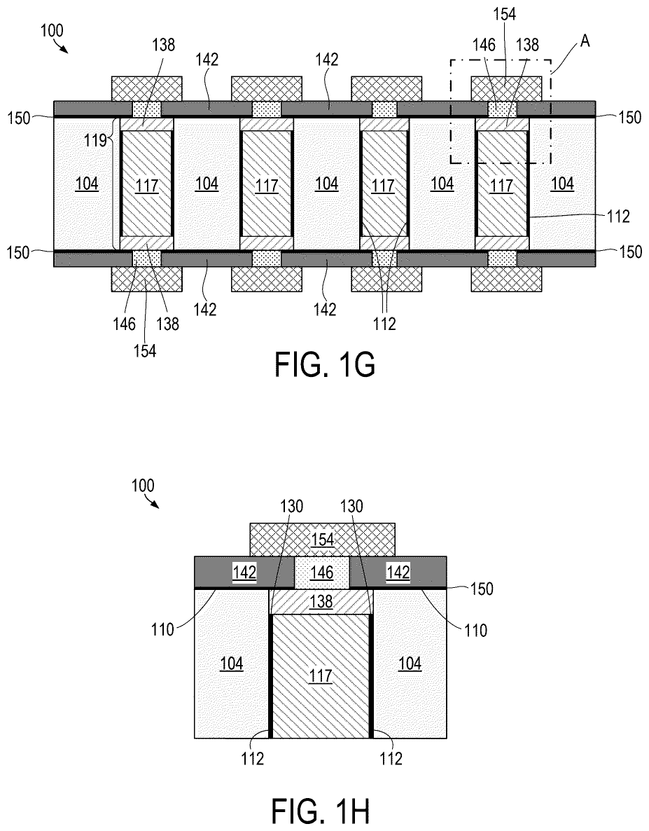

FIGS. 1A-1H are cross-sectional views of a first example structure comprising a glass layer (which can also be referred to as a glass core or a glass substrate) at various stages of manufacture. FIG. 1A illustrates a solid layer of glass 104 (glass layer) as a starting point for a structure 100.

In any of the embodiments described herein, the layer of glass 104 can be an amorphous solid glass layer. In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

Various suitable techniques can be utilized during processing of the structure 100 (and any other structure comprising a glass layer with through glass vias described or referenced herein). For example, film deposition—such as depositing layers, filling portions of layers (e.g., removed portions), and filling via openings—may be performed using any suitable deposition techniques, including, for example, chemical vapor deposition (CVD), metalorganic chemical vapor deposition (MOCVD), molecular beam epitaxy (MBE), atomic layer deposition (ALD), sputtering and/or physical vapor deposition (PVD). Moreover, patterning and removal—such as interconnect patterning, forming via openings, and shaping—may be performed using any suitable techniques, such as lithography-based patterning/masking, etching, and/or chemical-mechanical planarization (CMP).

FIG. 1B illustrates the structure 100 after formation of through-holes 108 in the glass layer 104. The through-holes 108 (or holes) extend from a top surface 110 to a bottom surface 114 of the glass layer 104. Any holes disclosed herein as being formed in a glass layer can be formed via laser-induced deep etching (LIDE) of the glass layer or by another suitable process. If the holes 108 (or any other holes described herein) are formed by an LIDE process, the cross-sectional profiles of the holes 108 are illustrated as idealized holes in that the sidewalls 109 of the holes are vertical. In practice, the sidewalls 109 of LIDE-generated holes can be tapered, with the width of the holes 108 narrowing from the top and bottom surfaces 110 and 114 of the glass layer 104 to the center of the glass layer 104, to create holes having an hourglass shape.

FIG. 1C illustrates the structure 100 after formation of layers 112 on the top and bottom surfaces 110 and 114 of the glass layer 104 and on the surfaces of the sidewalls 109 of the holes 108. The layers 112 can act as an adhesion promoter to promote adhesion of the through glass via (TGV) metal to the glass layer 104, a seed layer to enable filling of the holes 108 (by, for example, electroplating) by a TGV metal, and a diffusion barrier to prevent the TGV metal from diffusing into the glass layer 104. Similar seed/diffusion/adhesion layers can be formed on the sidewalls of any through-hole disclosed herein before the filling of the through-hole with a TGV metal. In some embodiments, the layers 112 comprises a first layer located on the sidewall 109 of the glass layer 104 and a second layer located on the first layer. The first layer can comprise titanium or another suitable material that can promote adhesion of metals to the glass layer 104, and the second layer can comprise copper, silver, gold, or another suitable electrically conductive material that can act as a seed layer for the TGV metal. For convenience, the layers (e.g., 112) that are formed on the sidewalls of holes in a glass layer may be referred to herein as “seed layers” even though the layers 112 can perform the functions of adhesion promotion and diffusion barrier in addition to acting as a seed layer during filling of a through-hole via plating.

FIG. 1D illustrates the structure 100 after plating of the structure 100 with through glass via metal 116. The TGV metal fills the through-holes 108 via fill-plating (i.e., the filling of the through-holes 108 via TGV metal forming on the seed layers 112 on the sidewalls 109 of the through-holes and filling the through-holes outward from there). The TGV metal 116 substantially fills the holes 108 and covers the top and bottom surfaces 110 and 114 of the glass layer 104. The TGV metal 116, as well as any other TGV metal disclosed or referenced herein (e.g., 216, 316) can comprise copper, nickel, tungsten, molybdenum, platinum, gold, silver, aluminum, another suitable metal, or a suitable alloy.

FIG. 1E illustrates the structure 100 after etching and planarization of the top and bottom surfaces of the structure 100 as illustrated in FIG. 1D. The etching and planarization remove the TGV metal 116 from the top and bottom surfaces 110 and 114 of the glass layer 104 and leave regions 117 of TGV metal (TGV metal regions 117) in the holes 108. FIG. 1E illustrates top recesses 120 that remain after the planarization process due to the top surfaces 122 of the TGV metal regions 117 coming to within a distance of the top surfaces 110, and bottom recesses 124 that remain after the planarization process due to the bottom surfaces 126 of the TGV metal regions 117 coming to within a distance of the bottom surfaces 114 of the glass layer 104. In some embodiments, the heights of recesses 120 and 124 (e.g., height 125 and 127, respectively) are in the range of about four microns to about ten microns. As a result of the etching and planarization of the TGV metal 116, the seed layers 112 are removed from the top and bottom surfaces 110 and 114 of the glass layer 104 and portions of the sidewalls 109 adjacent to the recesses 120 and 124. As a result, top ends 130 and bottom ends 134 of the seed layers 112 are substantially coincident with the top surfaces 122 and bottom surfaces 126, respectively, of the TGV metal regions 117. The structure 100 contains triple points 123 (where the glass layer 104, a TGV metal region 117, and air meet).

FIG. 1F illustrates the structure 100 after the recesses 120 and 124 are substantially filled with layers 138 to reduce local stress at the triple points 123 during downstream thermal processing of the structure 100. In some embodiments, the layers 138 can comprise a tin-based paste. In some embodiments, the tin-based paste can be doped with silver, copper, nickel, antimony, indium, palladium, or bismuth. In embodiments where the layers 138 comprises a tin-based paste, the paste comprises a binder. In embodiments where the layers 138 comprises a tin-based paste, the paste can further comprise one or more additives.

In other embodiments, the layer 138 can be formed via electroless plating. In such embodiments, the grain structure of the layers 138 can have a grain structure that is different from the grain structure of the TGV metal regions 117 (or bulk TGV regions). For example, in some embodiments, the sizes of the grains in the layers 138 can be less than the sizes of the grains in the TGV metal regions 117. In other embodiments, a substantial portion (more than 90%) of the grains in the layers 138 have a size within a first range of a grain sizes and a substantial portion (more than 90%) of the grains in the TGV metal regions 117 have a size within a second range of grain sizes. In some embodiments, the first range of grain sizes can be non-overlapping with the second range of grain sizes. That is, the high end of the first range of grain sizes is less than the lower end of the second range of grain sizes. In some embodiments, there can be overlap between the first range of grain sizes and the second range of grain sizes (e.g., the high end of the first range of grain sizes is greater than the lower end of the second range of grain sizes by no more than 25%). In some embodiments, the size of the grains in the layers 138 can be less than about one micron and the size of the grains in the TGV metal regions can be in the range of about one micron to about ten microns. In embodiments where the layers 138 are formed via electroless plating, the layers 138 can comprise copper, nickel, palladium, gold, silver, or other suitable metal.

Together, a TGV metal region 117 and layers 138 adjacent to top and bottom surfaces 122 and 126 of the TGV metal region 117 provide a conductive path through the glass layer 104 from the top surface 110 to the bottom surface 114 of the glass 104 to form a through glass via 119.

FIG. 1G illustrates the structure 100 after formation of a dielectric layer 142, vias 146, and pads 154 on top and bottom surfaces of the structure 100 as illustrated in FIG. 1F. The dielectric layer 142 can comprise an oxide, nitride, or another suitable dielectric. For example, dielectric layer 142 can comprise silicon and oxygen (e.g., SiOₓ, SiO₂), silicon and nitrogen (e.g., SiₓN_{y}, Si₃N₄), or Ajinomoto Build-up Film (ABF). ABF can be characterized as a material predominantly comprising carbon or a material predominantly comprising carbon as well as comprising nitrogen. The layer 142 can act as a buffer layer between the glass layer 104 and layers formed the glass layer during downstream processing. A layer 150 of material is positioned between the dielectric layer 142 and the top surfaces 110 and bottom surfaces 114 of the glass layer 104. The layer 150 can act as an adhesion layer to promote adhesion of the dielectric layer 142 to the glass layer 104. In some embodiments, the layer 150 comprises silicon nitride (e.g., SiN). The dielectric layers 142 and the layers 150 comprise openings that are located over or below the TGVs 119, and which are substantially filled by the vias 146. The vias 146 provide an electrically conductive connection between the pads 154 and the TGVs 119. The vias 146 and the pads 154 can comprise copper, nickel, tungsten, molybdenum, platinum, gold, silver, aluminum, another suitable metal, or a suitable alloy. The materials used in any of the TGV metal region 117, recesses 120 or 124, vias 146, or pads 154 can be the same as or different from those used in the others of the TGV metal region 117, recesses 120 or 124, vias 146, or pads 154.

The pads 154 can be part of a first redistribution layer (RDL) that is part of a stack of RDLs that connect an integrated circuit component to TGVs 119. The pads 154 are optional. In some embodiments, an integrated circuit component can be attached to the structure without the use of pads 154. For example, conductive contacts (e.g., microbumps) of an integrated circuit component can be attached directly to the vias 146. FIG. 1H is a detailed view of the portion A of FIG. 1G.

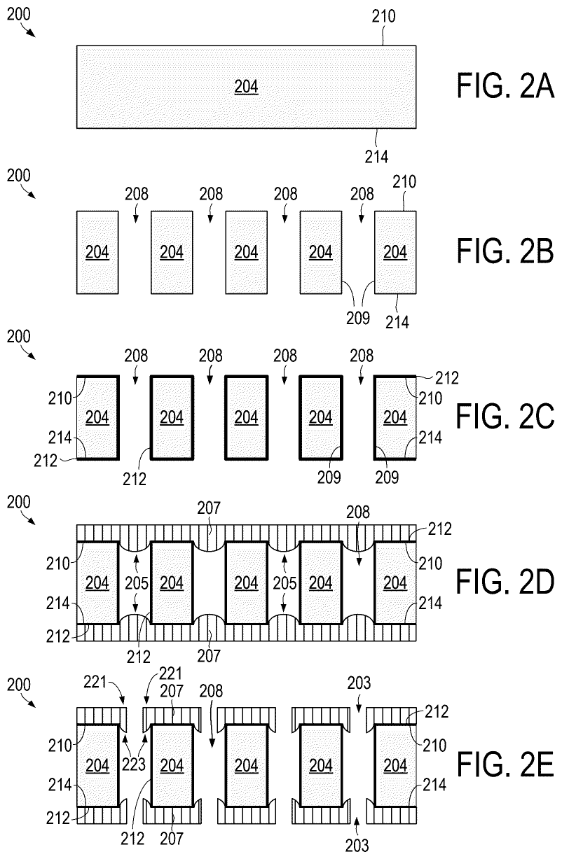

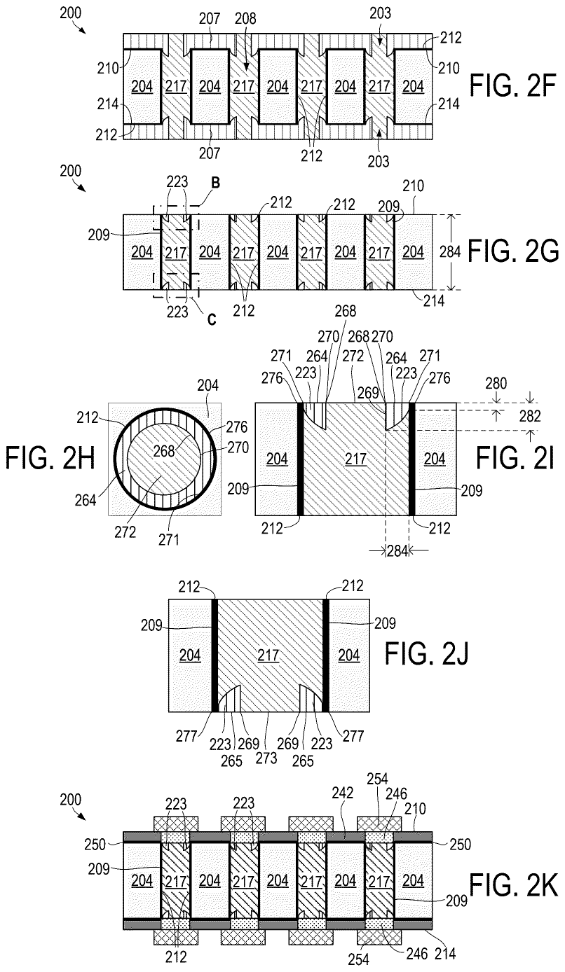

FIGS. 2A-2K are cross-sectional views of a second example structure comprising a glass layer at various stages of manufacture. The descriptions above for the elements and features of FIGS. 1A-1H apply to like-numbered elements features in FIGS. 2A-2K. For example, the layer of glass 204, layers 212, TGV metal region 217, and vias 246, are described by the descriptions provided above for layer of glass 104, layers 112, TGV metal region 117, and via 146, respectively.

FIGS. 2A-2C illustrate the structure 200 at processing stages similar to those illustrated in FIGS. 1A-1C. FIG. 2A illustrates a solid glass layer 204 as a starting point for a structure 200. FIG. 2B illustrates the structure 200 after formation of through-holes 208 in the layer of glass 204. The through-holes 208 extend from a top surface 210 to a bottom surface 214 of the layer of glass 204. FIG. 2C illustrates the structure 200 after formation of one or more seed layers 212 on the top surface 210, bottom surface 214, and sidewalls 209 of the glass layer 204. The layers 212 act as a seed layer for the TGV metal.

FIG. 2D illustrates the structure 200 after placement of layers 207 of a dielectric material on the top and bottom surfaces 210 and 214 of the layer of glass 204 via lamination. In some embodiments, layers 207 can be placed on and bonded to the layer of glass 204 via a dynamic lamination assembly (DLA) process. In other embodiments, the layers 207 can be placed or formed on the top and bottom surfaces 210 and 214 of the glass layer 204 via another suitable method. Layers 207 cover the holes 208 and form “tent” features 205 that extend into the holes 208. The tent features 205 are illustrated as having a rounded shape but can have other shapes. The layers 207 can comprise any low-modulus dielectric material that has a Young's modulus of about five gigapascals (GPa) or less, such as low-modulus Ajinomoto Buildup Film or encapsulation mold material. In some embodiments, the encapsulation mold material can comprise polymers of carbon and oxygen along with filler materials, such as silicon dioxide (silica) and/or other inorganic materials. The tent features of the layer 207 prevent the formation of air-glass-via triple points in the structure 200 and the low-modulus of the material forming the layer 207 allows the layers 207 to absorb stress in the structure 200 during downstream thermal treatment of the structure 200 to help prevent cracking or other damage in the layer of glass 204. In embodiments where ABF is used as the layer 207, the layers 207 may be only laminated over the openings of the holes 208, instead of being a continuous layer, as illustrated in FIG. 2D.

FIG. 2E illustrates the structure 200 after formation of openings 203 in the layers 207. The openings 203 can be formed by a photolithography process in embodiments where the layers 207 comprise a photoimageable dielectric, laser drilling, or by another suitable process. The openings 203 expose the holes 208 and leave overhangs 221 of the dielectric layers 207 that extend past the sidewalls 209 of the glass layer 204 and out over the through-holes 208. An overhang 221 comprises a portion 223 (overhang portion) that extends into a hole 208. An overhang portion 223 can be referred to as a “lip”. Overhangs 221 and overhang portions 223 will be discussed in greater detail below.

FIG. 2F illustrates the structure 200 after fill-plating of the structure 200 with through glass via metal. The TGV metal substantially fills the holes 208 in the glass layer 204 and substantially fills the openings 203 to create TGV metal regions 217.

FIG. 2G illustrates the structure 200 after etching and planarization of the top and bottom surfaces of the structure 200 as illustrated in FIG. 2F. An etching and planarization process removes the layers 207 from the top and bottom surfaces 210 and 214 of the glass layer 204 and leaves TGV metal regions 217 substantially filling the holes 208. As a result of the etching and the planarization process, lips 223 of the dielectric overhangs 221 remain as part of the structure 200. With reference to FIGS. 2H and 2I, which are detailed plan and cross-sectional views, respectively, of a portion B of the structure 200 as illustrated in FIG. 2H, a surface 264 of a lip 223 located at the top of the structure 200 is located between a perimeter 268 of a TGV metal region 217 at a top surface 272 of a TGV metal region 217 and a top perimeter 276 of a TGV sidewall 209. With reference to FIG. 2J, which is a cross-sectional view of a portion C of the structure 200 as illustrated in FIG. 2G, a bottom surface 265 of a lip 223 located at the bottom of the structure 200 is located between a perimeter 269 of a TGV metal region 217 at a bottom surface 273 of a TGV metal region 217 and a bottom perimeter 277 of a TGV sidewall 209.

The lips 223 as illustrated in FIGS. 2G-2K are annular in shape in plan view. In other embodiments, the lips 223 can have a rounded rectangular shape in plan view. The lips 223 can have a quarter-circle cross-sectional shape, as illustrated in FIGS. 2G and 2I-2K. The lips 223 can have other cross-sectional shapes in other embodiments, such as substantially triangular or substantially quarter-circle. In some embodiments, such as those illustrated in FIGS. 2G and 2I-2K, the lips 223 can have a first thickness (e.g., 282) at an inner perimeter 270 of the lip 223 that is greater than a second thickness (e.g., 280) at an outer perimeter 271 of the lip 223. In some embodiments, the maximum thickness that the lip 223 extends into the TGV metal region 217 (e.g., distance 282) is less than about 30%, less than about 25%, less than about 20%, or less than about 10% of a height (e.g., 284) of the glass layer. In some embodiments, the maximum thickness of the lip 223 extends into the TGV metal region 217 about 200 microns or less. The maximum thickness of the lip 223 can extend into the TGV metal region 217 by a distance that varies on the height of the glass layer. In some embodiments, the maximum thickness of the lip 223 can extend about 30 microns, about 50 microns, and about 100 microns for TGV metal region 217 heights of about 100, about 200, or about 400 microns or greater, respectively. In some embodiments, the minimum thickness of the lip 223 (e.g., distance 280) extends in the TGV metal region 217 by about 0.5 microns. In some embodiments, the width 284 of the lips can be less than about 10 microns, less than about 7 microns, or less than about 5 microns or less.

FIG. 2K illustrates the structure 200 after formation of a dielectric layer 242, vias 246, and pads 254 on top and bottom surfaces of the structure 200 illustrated in FIG. 2F. A layer 250 of material is positioned between the dielectric layer 242 and the top surfaces 210 and bottom surfaces 214 of the glass layer 204. The dielectric layers 242 and the layers 250 comprise openings that are located over or below the TGV metal regions 217, and which are substantially filled by the vias 246. The vias 246 provide an electrically conductive connection between the pads 254 and the TGV metal regions 217.

FIGS. 3A-3K are cross-sectional views of a third example structure comprising a glass layer at various stages of manufacture. One difference in the process illustrated in FIGS. 3A-3K from that illustrated in FIGS. 2A-2K is that dielectric layers (e.g., 207) used to create the tenting features remain as part of the structure and act as buffer layers between the glass layer and layers formed on the top and bottom to the glass layer in downstream processes, in addition to providing local stress relief. Keeping the dielectric layers 207 for use as buffer layers can reduce the number of processing steps to form TGVs.

The descriptions above for the elements and features of FIGS. 1A-2H and 2A-2K apply to like-numbered elements features in FIGS. 3A-3K. For example, layer 301, the layer of glass 304, TGV metal region 317, dielectric layer 307, and overhang portions 323, are described by the descriptions provided above for layer 212, layer of glass 104, TGV metal region 117, dielectric layer 207, and lips 223, respectively.

FIGS. 3A-3C illustrate processing steps similar to those illustrated in FIGS. 2A-2C. FIG. 3A illustrates a solid glass layer 304 as a starting point for a structure 300. FIG. 3B illustrates the structure 300 after formation of through-holes 308 in the layer of glass 304. The through-holes 308 extend from a top surface 310 to a bottom surface 314 of the layer of glass 304. FIG. 3C illustrates the structure 300 after formation of layers 301 on the top surface 310, bottom surface 314, and sidewalls 309 of the glass layer 304. The layers 301 act as adhesion promoter layers for the formation of dielectric layers 307.

FIG. 3D illustrates the structure 300 after placement of layers 307 comprising a dielectric material on the top and bottom surfaces 310 and 314 of the layer of glass 304 via lamination. Layers 307 cover the through-holes 308 and comprise low-modulus “tent” features 305 that extend into the through-holes 308 that prevent the formation of air-glass-metal triple points in the structure 300. FIG. 3E illustrates the structure 300 after formation of via openings 303 in the layers 307. The openings 303 expose the holes 308 and leave overhangs 321 of the dielectric layers 307 that extend past the sidewalls 309 and out over the holes 308. The overhangs 321 comprise lips 323 that extend into the holes 308.

FIG. 3F illustrates the structure 300 after formation of layers 311 (the light grey lines in FIG. 2F). In some embodiments, the layers 311 comprise first layers located on the layers 301 that are located on the sidewalls 309 and second layers located on the first layer. That is, a first layer of the layers 311 is positioned between a layer 301 and a second layer of the layers 311. The first layer can comprise titanium or other suitable material that can promote adhesion of through glass via metal to a layer 301, and the second layer comprises copper, silver, gold, or another suitable electrically conductive material that can act as a seed layer for the TGV metal. In some embodiments, the layers 311 comprise a single layer comprising copper or another suitable electrically conductive material that can act as a seed layer for the TGV metal.

FIG. 3G illustrates the structure 300 after plating of the structure 300 with TGV metal. The TGV metal substantially fills the holes 308 in the glass layer 304 and the openings 303 in the layers 307 to form TGV metal regions 317. With reference to FIGS. 3H and 3I, which are detailed plan and cross-sectional views, respectively, of a portion D of the structure 300 as illustrated in FIG. 3G, an overhang portion 323 positioned at the top of a TGV metal region 317 extends downwards a first distance 382 into a TGV metal region 317 at an inner perimeter 390 of the layer 307 at an opening 303 in the layer 307. The first distance 382 is greater than a second distance 380 into the TGV metal region 317 that the overhang portion 323 extends downwards at an outer perimeter 392 of the overhang portion 323. With reference to FIG. 3J, which is a detailed cross-sectional view of a portion E of the structure 300 as illustrated in FIG. 3G, an overhang portion 321 positioned at the bottom of a TGV metal region 317 extends upwards a first distance into the TGV metal region 317 a first distance at an inner perimeter 390 of the layer 307 at an opening 303 in the layer 307 that is greater than a second distance into the TGV metal region 317 that the overhang portion 323 extends upwards at an outer perimeter 392 of the overhang portion 323. The overhang portions 323 can have the shapes and properties as discussed above in regard to lips 223. FIG. 3K illustrates the structure 300 after the formation of pads 354 on top of bottom surfaces of the structure 300 illustrated in FIG. 3G.

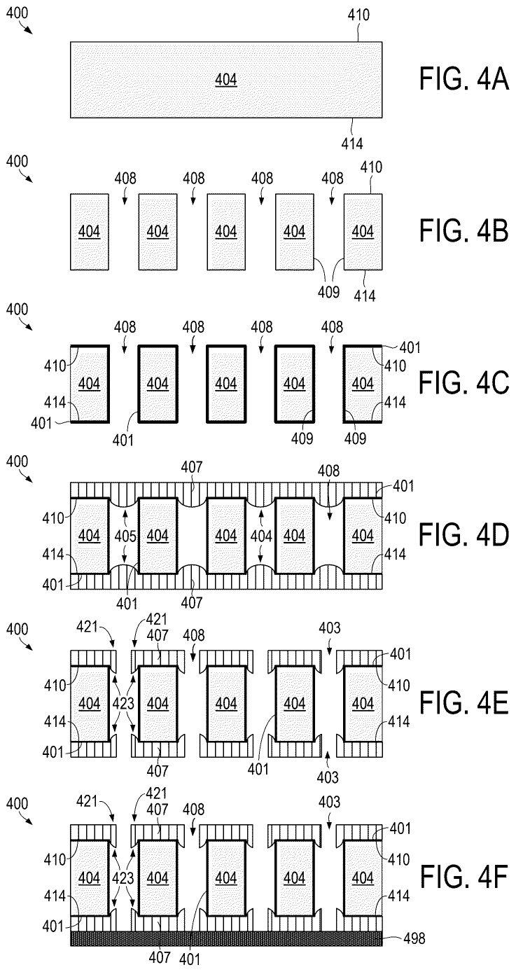

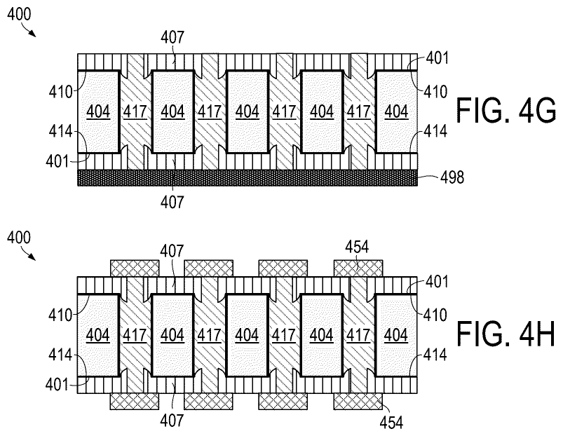

FIGS. 4A-4H are cross-sectional views of a fourth example structure comprising a glass layer at various stages of manufacture. The structure 400 formed via the processes illustrated in FIGS. 4A-4H is similar to the structure 300 formed by the processes illustrated in FIGS. 3A-3K but with the process illustrated in FIGS. 4A-4H employing bottom-up plating (instead of fill-plating) to fill the through-holes 408 with TGV metal via the use of a temporary carrier. The descriptions above for the elements and features of FIGS. 1A-2H and 2A-2K apply to like-numbered elements features in FIGS. 4A-4H. For example, layer 401, the layer of glass 404, TGV metal region 417, dielectric layer 407, and lips 423, are described by the descriptions provided above for layer 212, layer of glass 104, TGV metal region 117, dielectric layer 207, and lips 223 respectively.

FIGS. 4A-4E illustrate processing steps similar to those illustrated in FIGS. 3A-3E. FIG. 4A illustrates a solid glass layer 404 as a starting point for a structure 400. FIG. 4B illustrates the structure 400 after formation of through-holes 408 in the layer of glass 404. The through-holes 408 extend from a top surface 410 to a bottom surface 414 of the layer of glass 404. FIG. 4C illustrates the structure 400 after formation of layers 401 on the top surface 410, bottom surface 414, and sidewalls 409 of the glass layer 404. The layers 401 act as adhesion promotion layers for the formation of dielectric layers 407. FIG. 4D illustrates the structure 400 after placement of layers 407 comprising a dielectric material on the top and bottom surfaces 410 and 414 of the layer of glass 404 via lamination. Layers 407 cover the holes 408 and comprise low-modulus “tent” features 405 that extend into the holes 408 that prevent the formation of air-glass-metal triple points in the structure 400. FIG. 4E illustrates the structure 400 after the formation of via openings 403 in the layers 407. The openings 403 expose the holes 408 and leave overhangs 421 of the dielectric layers 407 that extend past the sidewalls 409 and out over the holes 408. The overhangs 421 comprise lips 423 that extend into the holes 408.

FIG. 4F illustrates the structure 400 after attachment of a carrier 498 to a bottom surface of the structure 400 as illustrated in FIG. 4E. The carrier 498 can act as a seed layer for the plating of TGV metal to fill the holes 408. The carrier 498 can comprise copper, aluminum or another suitable material. The use of the carrier 498 as the seed in TGV plating eliminates the need to form seed layers on the sidewalls 409 of the through-holes 408.

FIG. 4G illustrates the structure 400 after bottom-up plating of the structure 400 with through glass via metal. With the carrier 498 acting as a seed layer for the TGV metal, the TGV metal substantially fills the holes 408 in a bottom-up manner to form TGV metal regions 417. After bottom-up plating of the TGV metal, the TGV metal may extend past the top surfaces of the layers 407. A planarization process can be performed to planarize the top of the structure 400. FIG. 4G illustrates the structure 400 after TGV metal plating and subsequent planarization. FIG. 4H illustrates the structure 400 after removal of the carrier 498 and formation of pads 454 on top of bottom surfaces of the structure 400 illustrated in FIG. 4G.

While FIGS. 4A-4H illustrates a process in which bottom-up plating is used to form TGVs in the structure 400, bottom-up plating can be used in TGV formation in other structures disclosed herein, such as structure 100.

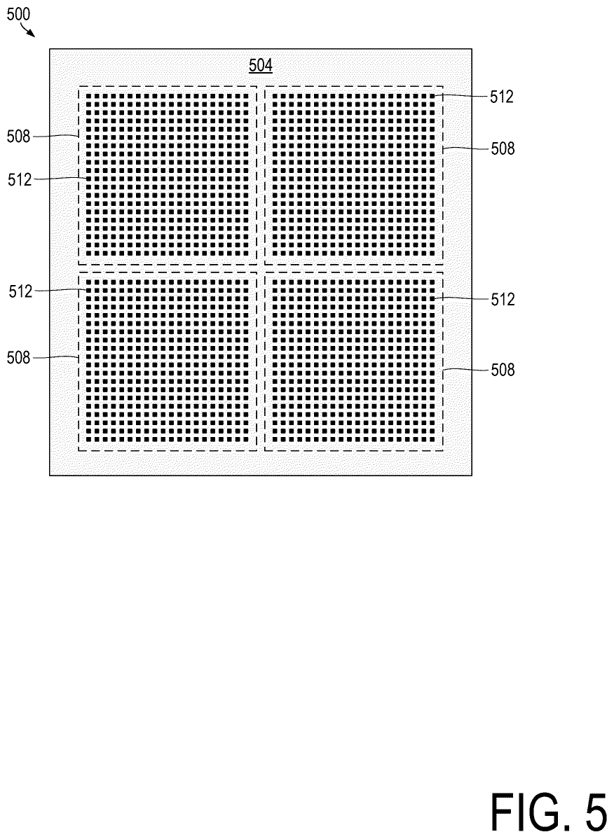

FIG. 5 is a plan view of a fifth example structure comprising a layer of glass comprising through glass vias that have been formed according to any of the embodiments disclosed herein. The structure 500 comprises a layer of glass 504 that has a rectangular shape in plan view and a plurality of TGVs 512 have been formed in the layer of glass 504. The TGVs 512 provide electrical connectivity for integrated circuit components 508 (whose outlines are represented with dashed lines) to other components to be attached to the layer of glass 504 or located elsewhere in a computing system within which the structure 500 is to be located.

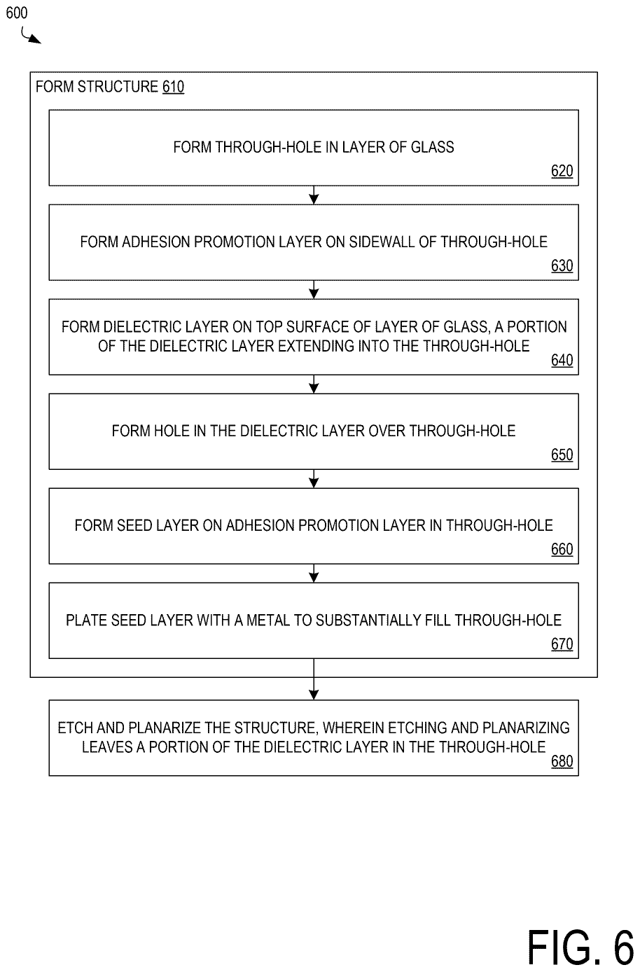

FIG. 6 is a second example method of forming through-glass vias. At 610 in the method 600, a structure is formed. Forming the structure can comprise the following. At 620, a through-hole is formed in a layer of glass, wherein the layer of glass is solid and has a rectangular shape in plan view, and wherein the through-hole extends from a top surface of the layer of glass to a bottom surface of the layer of glass. At 630, an adhesion promotion layer is formed on a sidewall of the through-hole, the top surface of the layer of glass, and the bottom surface of the layer of glass. At 640, a dielectric layer is formed on the top surface of the layer of glass, a portion of the dielectric layer extending into the through-hole. At 650, a hole is formed in the dielectric layer, the hole positioned over the through-hole. At 660, a seed layer is formed on the adhesion promotion layer in the through-hole. At 670, the seed layer is plated with a metal, wherein the through-hole is substantially filled with the metal as a result of the plating. After formation of the structure, at 680, the structure is etched and planarized, wherein etching and planarizing leaves a region of the metal that substantially fills the through-hole, and leaves a portion of the dielectric layer in the through-hole, wherein a top surface of the region of the metal has a first perimeter and the through-hole has a second perimeter at the top surface of the layer of glass, the portion of the dielectric layer in the through-hole having a top surface located between the first perimeter and the second perimeter, the portion of the dielectric layer in the through-hole extending into the through-hole a maximum distance of less than 10% of a height of the layer of glass.

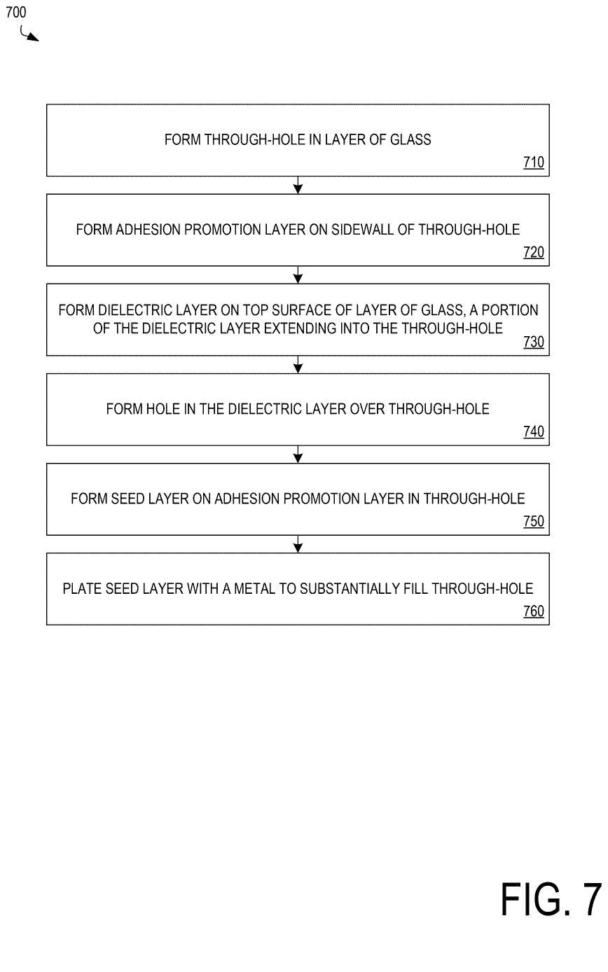

FIG. 7 is a third example method of forming through-glass vias. At 710 in the method 700, a through-hole is formed in a layer of glass, wherein the layer of glass is solid and has a rectangular shape in plan view, and wherein the through-hole extends from a top surface of the layer of glass to a bottom surface of the layer of glass. At 720, an adhesion promotion layer is formed on a sidewall of the through-hole, the top surface of the layer of glass, and the bottom surface of the layer of glass. At 730, a dielectric layer is formed on the top surface of the layer of glass, a portion of the dielectric layer extending into the through-hole, the dielectric layer comprising a dielectric material. At 740, an opening is formed in the dielectric layer, the opening positioned over the through-hole, the dielectric layer comprising, as a result of forming the opening in the dielectric layer, an overhang that extends past a sidewall of the through-hole, wherein the overhang comprises an overhang portion that extends into the through-hole. At 750, a seed layer is formed on the adhesion promotion layer in the through-hole. At 760, the seed layer is plated with a metal, wherein the through-hole is substantially filled with the metal as a result of plating.

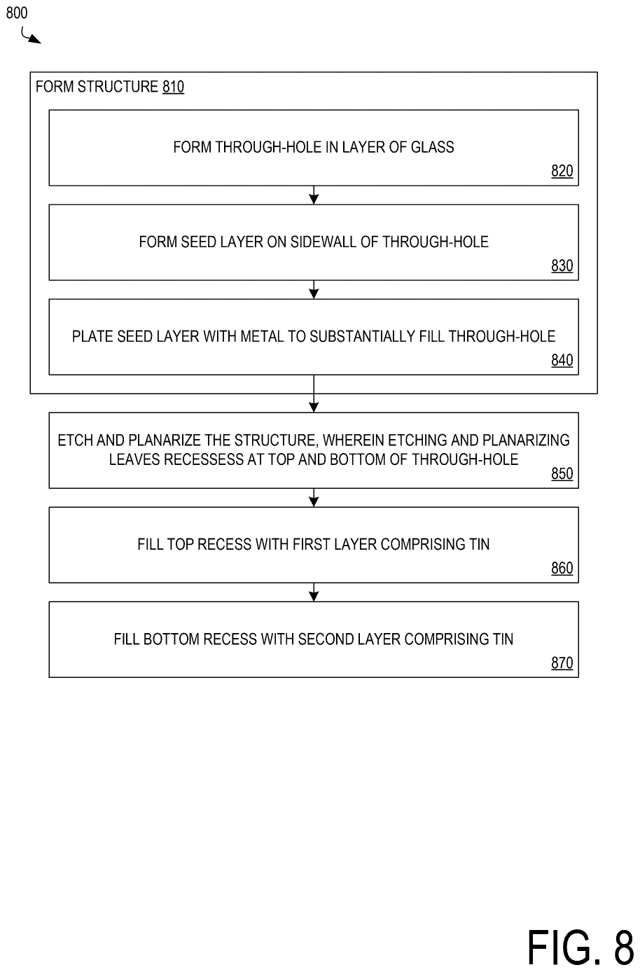

FIG. 8 is a first example method of forming through-glass vias. At 810 in the method 800, a structure is formed. Forming the structure can comprise the following. At 820, a through-hole is formed in a layer of glass, wherein the layer of glass is solid and has a rectangular shape in plan view, and wherein the through-hole extends from a top surface of the layer of glass to a bottom surface of the layer of glass. At 830, a seed layer is formed on a sidewall of the through-hole, the top surface of the layer of glass, and the bottom surface of the layer of glass. At 840, the seed layer is plated with a first metal, wherein the through-hole is substantially filled with the first metal as a result of plating and a substantial portion of grains of the first metal have a size within a first range of sizes. After formation of the structure, at 850, the structure is etched and planarized, wherein, etching and planarizing leaves a first region of the first metal that substantially fills the through-hole, a first recess in the through-hole at the top surface of the first region, and a second recess in the through-hole at the bottom surface of the first region. At 860, the first recess is substantially filled with a first layer comprising tin. At 870, the second recess is substantially filled with a second layer comprising tin.

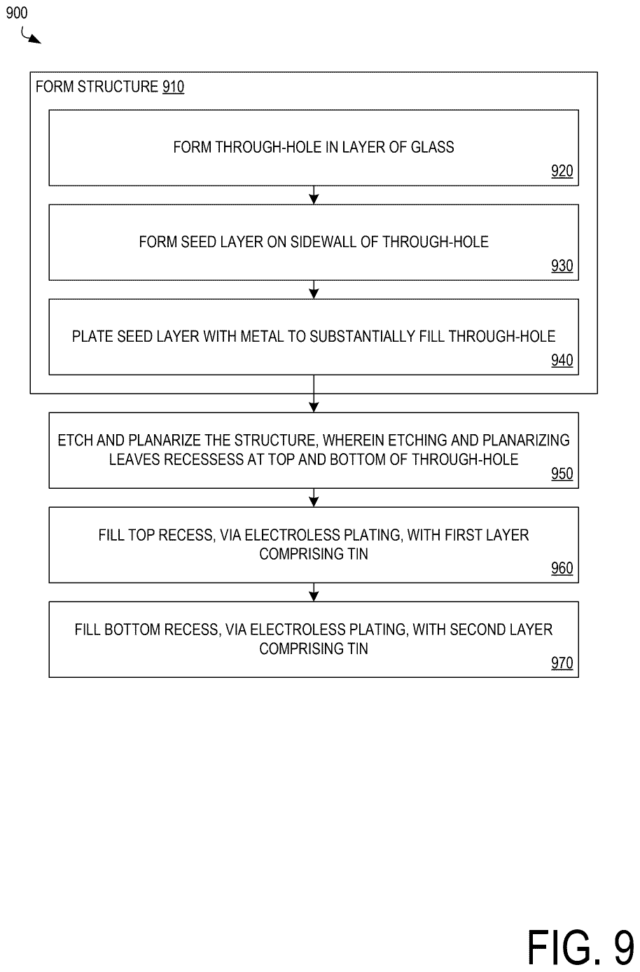

FIG. 9 is a first example method of forming through-glass vias. At 910 in the method 900, a structure is formed. Forming the structure can comprise the following. At 920, a through-hole is formed in a layer of glass, wherein the layer of glass is solid and has a rectangular shape in plan view, and wherein the through-hole extends from a top surface of the layer of glass to a bottom surface of the layer of glass. At 930, a seed layer is formed on a sidewall of the through-hole, the top surface of the layer of glass, and the bottom surface of the layer of glass. At 940, the seed layer is plated with a first metal, wherein the through-hole is substantially filled with the first metal as a result of plating and a substantial portion of grains of the first metal have a size within a first range of sizes. After formation of the structure, at 950, the structure is etched and planarized, wherein, etching and planarizing leaves a first region of the first metal that substantially fills the through-hole, a first recess in the through-hole at the top surface of the first region, and a second recess in the through-hole at the bottom surface of the first region. At 960, the first recess is substantially filled, via electroless plating, with a first layer comprising tin. At 970, the second recess is substantially filled, via electroless plating, with a second layer comprising tin.

The methods 600, 700, 800, and 900 can have more or fewer actions than shown. In some embodiments, multiple actions in these methods can be combined or individual actions can be split up into multiple actions.

The glass layers described herein can have any processor unit or integrated circuit component described or referenced herein attached to it, either directly or by one or more intervening routing layers, such as redistribution layers (RDLs). Any structure comprising a glass layer with TGVs (e.g., 100, 200, 300, 400) to which one or more integrated circuit components are attached can be referred to as a microelectronic assembly. The glass layers can also be attached to a printed circuit board. In some embodiments, one or more additional integrated circuit components or other components, such as a battery or antenna, can be attached to a printed circuit board to which a glass layer is attached. In some embodiments, the printed circuit board and the integrated circuit component can be located in a computing device that comprises a housing that encloses the printed circuit board and the glass layer.

It is to be understood that drawings illustrate idealized versions of structure cross-sections. In actual cross-sections, the lines, layers, and other elements illustrated in the drawings can have shapes that vary from those illustrated. For example, surfaces illustrated as planar possess undulations, bumps, or dishing features; sidewalls can have a taper to them; ninety-degree corners can be rounded; and lines, layers, and features can overlap more or less than illustrated.

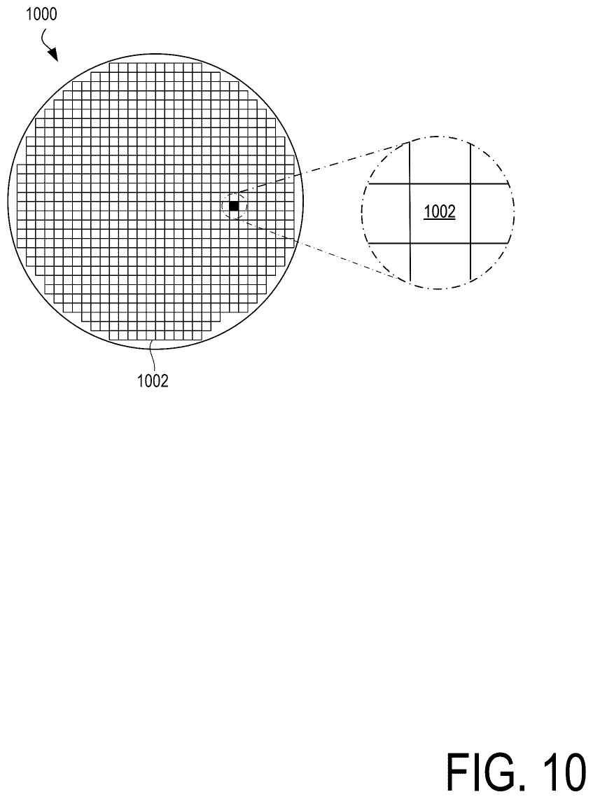

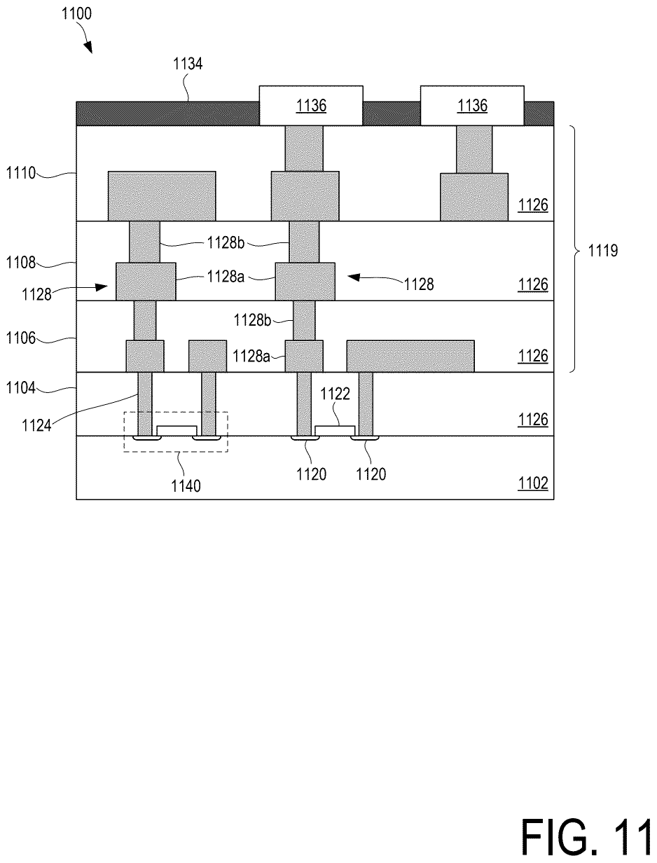

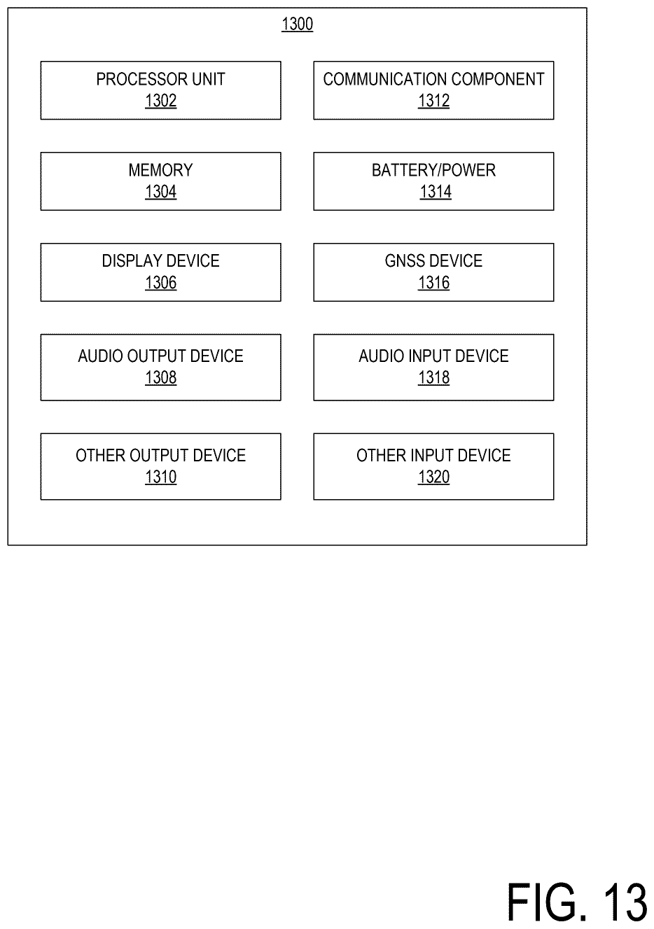

FIG. 10 is a top view of a wafer 1000 and dies 1002 that may be included in any microelectronic assemblies comprising a glass layer (e.g., 100, 200, 300, 400) disclosed herein. The wafer 1000 may be composed of semiconductor material and may include one or more dies 1002 having integrated circuit structures formed on a surface of the wafer 1000. The individual dies 1002 may be a repeating unit of an integrated circuit product that includes any suitable integrated circuit. After the fabrication of the semiconductor product is complete, the wafer 1000 may undergo a singulation process in which the dies 1002 are separated from one another to provide discrete “chips” of the integrated circuit product. The die 1002 may include one or more transistors (e.g., some of the transistors 1140 of FIG. 11, discussed below), supporting circuitry to route electrical signals to the transistors, passive components (e.g., signal traces, resistors, capacitors, or inductors), and/or any other integrated circuit components. In some embodiments, the wafer 1000 or the die 1002 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1002. For example, a memory array formed by multiple memory devices may be formed on a same die 1002 as a processor unit (e.g., the processor unit 1302 of FIG. 13) or other logic that is configured to store information in the memory devices or execute instructions stored in the memory array. Various ones of the microelectronic assemblies disclosed herein may be manufactured using a die-to-wafer assembly technique in which some dies are attached to a wafer 1000 that include others of the dies, and the wafer 1000 is subsequently singulated.

FIG. 11 is a cross-sectional side view of an integrated circuit device 1100 that may be included in any of the microelectronic assemblies disclosed herein, such as a die included in a packaged integrated circuit component attached to a glass layer having TGVs. One or more of the integrated circuit devices 1100 may be included in one or more dies 1002 (FIG. 10). The integrated circuit device 1100 may be formed on a die substrate 1102 (e.g., the wafer 1000 of FIG. 10) and may be included in a die (e.g., the die 1002 of FIG. 10). The die substrate 1102 may be a semiconductor substrate composed of semiconductor material systems including, for example, n-type or p-type materials systems (or a combination of both). The die substrate 1102 may include, for example, a crystalline substrate formed using a bulk silicon or a silicon-on-insulator (SOI) substructure. In some embodiments, the die substrate 1102 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1102. Although a few examples of materials from which the die substrate 1102 may be formed are described here, any material that may serve as a foundation for an integrated circuit device 1100 may be used. The die substrate 1102 may be part of a singulated die (e.g., the dies 1002 of FIG. 10) or a wafer (e.g., the wafer 1000 of FIG. 10).

The integrated circuit device 1100 may include one or more device layers 1104 disposed on the die substrate 1102. The device layer 1104 may include features of one or more transistors 1140 (e.g., metal oxide semiconductor field-effect transistors (MOSFETs)) formed on the die substrate 1102. The transistors 1140 may include, for example, one or more source and/or drain (S/D) regions 1120, a gate 1122 to control current flow between the S/D regions 1120, and one or more S/D contacts 1124 to route electrical signals to/from the S/D regions 1120. The transistors 1140 may include additional features not depicted for the sake of clarity, such as device isolation regions, gate contacts, and the like. The transistors 1140 are not limited to the type and configuration depicted in FIG. 11 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 1140 may include a gate 1122 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1140 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1140 along the source-channel-drain direction, the gate electrode may consist of a U-shaped structure that includes a bottom portion substantially parallel to the surface of the die substrate 1102 and two sidewall portions that are substantially perpendicular to the top surface of the die substrate 1102. In other embodiments, at least one of the metal layers that form the gate electrode may simply be a planar layer that is substantially parallel to the top surface of the die substrate 1102 and does not include sidewall portions substantially perpendicular to the top surface of the die substrate 1102. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1120 may be formed within the die substrate 1102 adjacent to the gate 1122 of individual transistors 1140. The S/D regions 1120 may be formed using an implantation/diffusion process or an etching/deposition process, for example. In the former process, dopants such as boron, aluminum, antimony, phosphorous, or arsenic may be ion-implanted into the die substrate 1102 to form the S/D regions 1120. An annealing process that activates the dopants and causes them to diffuse farther into the die substrate 1102 may follow the ion-implantation process. In the latter process, the die substrate 1102 may first be etched to form recesses at the locations of the S/D regions 1120. An epitaxial deposition process may then be carried out to fill the recesses with material that is used to fabricate the S/D regions 1120. In some implementations, the S/D regions 1120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1120 may be formed using one or more alternate semiconductor materials such as germanium or a group III-V material or alloy. In further embodiments, one or more layers of metal and/or metal alloys may be used to form the S/D regions 1120.

Electrical signals, such as power and/or input/output (I/O) signals, may be routed to and/or from the devices (e.g., transistors 1140) of the device layer 1104 through one or more interconnect layers disposed on the device layer 1104 (illustrated in FIG. 11 as interconnect layers 1106-1110). For example, electrically conductive features of the device layer 1104 (e.g., the gate 1122 and the S/D contacts 1124) may be electrically coupled with the interconnect structures 1128 of the interconnect layers 1106-1110. The one or more interconnect layers 1106-1110 may form a metallization stack (also referred to as an “ILD stack”) 1119 of the integrated circuit device 1100.

The interconnect structures 1128 may be arranged within the interconnect layers 1106-1110 to route electrical signals according to a wide variety of designs; in particular, the arrangement is not limited to the particular configuration of interconnect structures 1128 depicted in FIG. 11. Although a particular number of interconnect layers 1106-1110 is depicted in FIG. 11, embodiments of the present disclosure include integrated circuit devices having more or fewer interconnect layers than depicted.

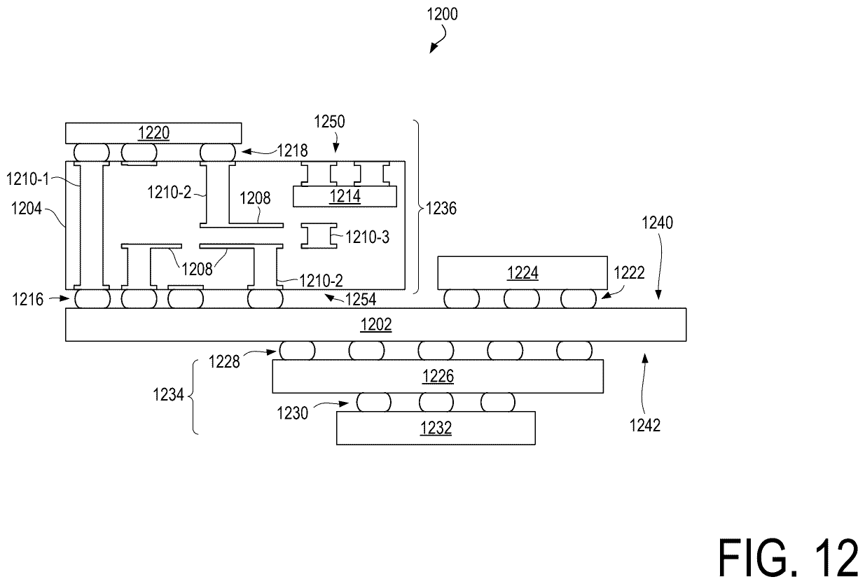

In some embodiments, the interconnect structures 1128 may include lines 1128a and/or vias 1128b filled with an electrically conductive material such as a metal. The lines 1128a may be arranged to route electrical signals in a direction of a plane that is substantially parallel with a surface of the die substrate 1102 upon which the device layer 1104 is formed. For example, the lines 1128a may route electrical signals in a direction in and out of the page and/or in a direction across the page from the perspective of FIG. 12. The vias 1128b may be arranged to route electrical signals in a direction of a plane that is substantially perpendicular to the surface of the die substrate 1102 upon which the device layer 1104 is formed. In some embodiments, the vias 1128b may electrically couple lines 1128a of different interconnect layers 1106-1110 together.

The interconnect layers 1106-1110 may include a dielectric material 1126 disposed between the interconnect structures 1128, as shown in FIG. 11. In some embodiments, dielectric material 1126 disposed between the interconnect structures 1128 in different ones of the interconnect layers 1106-1110 may have different compositions; in other embodiments, the composition of the dielectric material 1126 between different interconnect layers 1106-1110 may be the same. The device layer 1104 may include a dielectric material 1126 disposed between the transistors 1140 and a bottom layer of the metallization stack as well. The dielectric material 1126 included in the device layer 1104 may have a different composition than the dielectric material 1126 included in the interconnect layers 1106-1110; in other embodiments, the composition of the dielectric material 1126 in the device layer 1104 may be the same as a dielectric material 1126 included in any one of the interconnect layers 1106-1110.

A first interconnect layer 1106 (referred to as Metal 1 or “M1”) may be formed directly on the device layer 1104. In some embodiments, the first interconnect layer 1106 may include lines 1128a and/or vias 1128b, as shown. The lines 1128a of the first interconnect layer 1106 may be coupled with contacts (e.g., the S/D contacts 1124) of the device layer 1104. The vias 1128b of the first interconnect layer 1106 may be coupled with the lines 1128a of a second interconnect layer 1108.

The second interconnect layer 1108 (referred to as Metal 2 or “M2”) may be formed directly on the first interconnect layer 1106. In some embodiments, the second interconnect layer 1108 may include via 1128b to couple the lines 1128 of the second interconnect layer 1108 with the lines 1128a of a third interconnect layer 1110. Although the lines 1128a and the vias 1128b are structurally delineated with a line within individual interconnect layers for the sake of clarity, the lines 1128a and the vias 1128b may be structurally and/or materially contiguous (e.g., simultaneously filled during a dual-damascene process) in some embodiments.

The third interconnect layer 1110 (referred to as Metal 3 or “M3”) (and additional interconnect layers, as desired) may be formed in succession on the second interconnect layer 1108 according to similar techniques and configurations described in connection with the second interconnect layer 1108 or the first interconnect layer 1106. In some embodiments, the interconnect layers that are “higher up” in the metallization stack 1119 in the integrated circuit device 1100 (i.e., farther away from the device layer 1104) may be thicker that the interconnect layers that are lower in the metallization stack 1119, with lines 1128a and vias 1128b in the higher interconnect layers being thicker than those in the lower interconnect layers.

The integrated circuit device 1100 may include a solder resist material 1134 (e.g., polyimide or similar material) and one or more conductive contacts 1136 formed on the interconnect layers 1106-1110. In FIG. 11, the conductive contacts 1136 are illustrated as taking the form of bond pads. The conductive contacts 1136 may be electrically coupled with the interconnect structures 1128 and configured to route the electrical signals of the transistor(s) 1140 to external devices. For example, solder bonds may be formed on the one or more conductive contacts 1136 to mechanically and/or electrically couple an integrated circuit die including the integrated circuit device 1100 with another component (e.g., a printed circuit board). The integrated circuit device 1100 may include additional or alternate structures to route the electrical signals from the interconnect layers 1106-1110; for example, the conductive contacts 1136 may include other analogous features (e.g., posts) that route the electrical signals to external components. The conductive contacts 1136 may serve as the pads (154, 254, 354, 454), as appropriate.

In some embodiments in which the integrated circuit device 1100 is a double-sided die, the integrated circuit device 1100 may include another metallization stack (not shown) on the opposite side of the device layer(s) 1104. This metallization stack may include multiple interconnect layers as discussed above with reference to the interconnect layers 1106-1110, to provide conductive pathways (e.g., including conductive lines and vias) between the device layer(s) 1104 and additional conductive contacts (not shown) on the opposite side of the integrated circuit device 1100 from the conductive contacts 1136. These additional conductive contacts may also serve as the pads (154, 254, 354, 454), as appropriate.

In other embodiments in which the integrated circuit device 1100 is a double-sided die, the integrated circuit device 1100 may include one or more through silicon vias (TSVs) through the die substrate 1102; these TSVs may make contact with the device layer(s) 1104, and may provide conductive pathways between the device layer(s) 1104 and additional conductive contacts (not shown) on the opposite side of the integrated circuit device 1100 from the conductive contacts 1136. These additional conductive contacts may serve as the pads (154, 254, 354, 454), as appropriate. In some embodiments, TSVs extending through the substrate can be used for routing power and ground signals from conductive contacts on the opposite side of the integrated circuit device 1100 from the conductive contacts 1136 to the transistors 1140 and any other components integrated into the die 1100, and the metallization stack 1119 can be used to route I/O signals from the conductive contacts 1136 to transistors 1140 and any other components integrated into the die 1100.

Multiple integrated circuit devices 1100 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 12 is a cross-sectional side view of an integrated circuit device assembly 1200 that may include any of the microelectronic assemblies disclosed herein comprising a glass layer with through glass vias. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may take the form of any suitable ones of the integrated circuit components disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. In other embodiments, the circuit board 1302 can comprise any of the glass layers comprising TGVs disclosed herein.

The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1216 may serve as the coupling components illustrated or described for any of the substrate assembly or substrate assembly components described herein, as appropriate.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204.

The integrated circuit component 1220 may be a packaged or unpacked integrated circuit product that includes one or more integrated circuit dies (e.g., the die 1002 of FIG. 10, the integrated circuit device 1100 of FIG. 11) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through-hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, the interposer 1304 can comprise a glass layer comprising through glass vias. In some embodiments, an interposer 1204 comprising a silicon interposer or a glass layer can further comprise one or more routing layers, such as redistribution layers (RDLs) to route connections on a first face of the interposer 1204 to an opposing second face of the interposer 1204. These routing layers can be located on either of both faces of the interposer 1304.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art. In embodiments where the interposer is a non-printed circuit board

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one or more of the microelectronic assemblies disclosed herein. For example, any suitable ones of the components of the electrical device 1300 may include one or more of the integrated circuit device assemblies 1200, integrated circuit components 1220, integrated circuit devices 1100, or integrated circuit dies 1002 disclosed herein, and may be arranged in any of the microelectronic assemblies disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1318 or an audio output device 1308, but may include audio input or output device interface circuitry (e.g., connectors and supporting circuitry) to which an audio input device 1318 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1(L1 ), Level 2(L2 ), Level 3(L3 ), Level 4(L4 ), Last Level Cache (LLC)) and may include embedded dynamic random-access memory (eDRAM) or spin transfer torque magnetic random-access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1318 (or corresponding interface circuitry, as discussed above). The audio input device 1318 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1316 (or corresponding interface circuitry, as discussed above), such as a Global Positioning System (GPS) device. The GNSS device 1316 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include an other input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example A1 is an apparatus, comprising: a layer of glass; and a through-hole extending from a top surface of the layer of glass to a bottom surface of the layer of glass, wherein a first metal substantially fills a first region of the through-hole to within a first distance from the top surface of the layer of glass and to within a second distance from the bottom surface of the layer of glass, wherein a second metal substantially fills a second region of the through-hole located between a top surface of the first region and the top surface of the layer of glass, and wherein the second metal substantially fills a third region of the through-hole located between the bottom surface of the first region and the bottom surface of the layer of glass.

Example A2 includes the apparatus of Example A1, wherein the second metal is tin.

Example A3 includes the apparatus of Example A1, wherein the second region and the third region further comprise silver, copper, nickel, antimony, indium, palladium, or bismuth.

Example A4 includes the apparatus of Example A1, wherein the second region and the third region comprise a paste comprising the second metal.

Example A5 includes the apparatus of any one of Examples A1-A4, wherein the layer of glass comprises: silicon; oxygen; and one or more of aluminum, boron, magnesium, calcium, barium, tin, sodium, potassium, strontium, phosphorous, zirconium, lithium, titanium, and zinc.

Example A6 includes the apparatus of any one of Examples A1-A4, wherein the layer of glass comprises aluminosilicate glass, borosilicate glass, alumino-borosilicate glass, silica, or fused silica.

Example A7 includes the apparatus of any one of Examples A1-A4, wherein the layer of glass comprises at least 23 percent silicon by weight, at least 26 percent oxygen by weight, and further comprises at least 5 percent aluminum by weight.

Example A8 includes the apparatus of any one of Examples A1-A4, wherein the layer of glass does not include an organic adhesive or an organic material.

Example A9 includes the apparatus of any one of Examples A1-A4, wherein the layer of glass is amorphous.

Example A9.1 includes the apparatus of any one of Examples A1-A4, wherein the layer of glass is solid and has a rectangular shape in plan view.

Example A10 is an apparatus, comprising: a layer of glass; and a through-hole extending from a top surface of the layer of glass to a bottom surface of the layer of glass, wherein a first metal substantially fills a first region of the through-hole to within a first distance from the top surface of the layer of glass and to within a second distance from the bottom surface of the layer of glass, wherein a substantial portion of grains of the first region have a size within a first range of grain sizes; wherein a second metal substantially fills a second region of the through-hole located between a top surface of the first metal and the top surface of the layer of glass, wherein the second metal substantially fills a third region of the through-hole located between the bottom surface of the first metal and the bottom surface of the layer of glass, wherein a substantial portion of grains of the second region and the third region are within a second range of grain sizes, wherein a lower end of the first range of grain sizes is greater than a higher end of the second range of grain sizes.

Example A11 includes the apparatus of Example A10 wherein the first range of grain sizes is about one micron to ten microns and the second range of grain sizes is less than about one micron.

Example A12 includes the apparatus of Example A10 or 11, wherein the second metal comprises is copper.

Example A13 includes the apparatus of Example A10 or 11, wherein the second metal comprises is nickel, palladium, gold, or silver.

Example A14 includes the apparatus of any one of Examples A10-A13, wherein the layer of glass comprises at least 23 percent silicon by weight, at least 26 percent oxygen by weight, and further comprises at least 5 percent aluminum by weight.

Example A15 includes the apparatus of any one of Examples A10-A13, wherein the layer of glass does not include an organic adhesive or an organic material.

Example A16 includes the apparatus of any one of Examples A10-A15, wherein the layer of glass is amorphous.

Example A17 includes the apparatus of any one of Examples A10-A16, wherein the layer of glass is a solid glass layer and has a rectangular shape in plan view.

Example A17.1 includes the apparatus of any one of Examples A10-A16, wherein the layer of glass comprises silicon, oxygen, and aluminum.

Example A18 includes the apparatus of any one of Examples A1-A17, where the first metal is copper.

Example A19 includes the apparatus of any one of Examples A1-A17, where the first metal is nickel, tungsten, molybdenum, platinum, gold, silver, or aluminum.

Example A20 includes the apparatus of any one of Examples A1-A19, further comprising: a first layer comprising a third metal, the first layer located on a sidewall of the through-hole, a top end of the first layer substantially coincident with the top surface of the first region, a bottom end of the first layer substantially coincident with the bottom surface of the first region; and a second layer comprising a fourth metal, the second layer located on the first layer and between the first layer and the first region, a top end of the second layer substantially coincident with the top surface of the first region, a bottom end of the second layer substantially coincident with the bottom surface of the first region.

Example A21 includes the apparatus of Example A20, wherein the first layer comprises titanium and the second layer comprises copper.

Example A22 includes the apparatus of Example A20, wherein the first layer comprises titanium and the second layer comprises silver or gold.

Example A23 includes the apparatus of any one of Examples A1-A20, further comprising: a first layer comprising silicon and nitrogen located on the top surface of the layer of glass, the first layer comprising a first opening over the first region; and a second layer comprising a dielectric material located on the first layer, wherein the second layer comprises a second opening over the first region.

Example A24 includes the apparatus of Example A23, wherein the dielectric material comprises carbon and nitrogen.

Example A25 includes the apparatus of Example A23, wherein the dielectric material comprises Ajinomoto Build-Up Film.

Example A26 includes the apparatus of any one of Examples A23-A25, wherein the dielectric material comprises polymers comprising carbon and oxygen.

Example A27 includes the apparatus of any Example A26, wherein the dielectric material further comprises silicon.

Example A28 includes the apparatus of any one of Examples A23-A25, further comprising a third layer comprising a third metal, the third layer substantially filling the first opening and the second opening.

Example A29 includes the apparatus any one of Examples A28, wherein the third metal is copper.

Example A30 includes the apparatus of any one of Examples A28, wherein the third metal is silver, gold, nickel, tungsten, cobalt, or aluminum.

Example A31 is a device comprising: a layer of glass; a through-hole extending from a top surface of the layer of glass to a bottom surface of the layer of glass, wherein a first metal substantially fills a first region of the through-hole to within a first distance from the top surface of the layer of glass and to within a second distance from the bottom surface of the layer of glass, wherein a second metal substantially fills a second region of the through-hole located between a top surface of the first region and the top surface of the layer of glass, and wherein the second metal substantially fills a third region of the through-hole located between the bottom surface of the first region and the bottom surface of the layer of glass; and an integrated circuit component located on the top surface of the layer of glass, a conductive contact of the integrated circuit component electrically coupled to the first region.

Example A32 includes the device of Example A31, wherein the second metal is tin.

Example A33 includes the device of Example A31, wherein the second region and the third region further comprise silver, copper, nickel, antimony, indium, palladium, or bismuth.

Example A34 includes the device of Example A31, wherein the second region and the third region comprise a paste comprising the second metal.

Example A35 includes the device of any one of Examples A31-A34, wherein the layer of glass does not include an organic adhesive or an organic material.

Example A36 includes the device of any one of Examples A31-A35, wherein the layer of glass is amorphous.

Example A37 includes the device of any one of Examples A31-A36, wherein the layer of glass is a solid glass layer and has a rectangular shape in plan view.

Example A38 is a device, comprising: a layer of glass comprising silicon, oxygen, and aluminum; a through-hole extending from a top surface of the layer of glass to a bottom surface of the layer of glass, wherein a first metal substantially fills a first region of the through-hole to within a first distance from the top surface of the layer of glass and to within a second distance from the bottom surface of the layer of glass, wherein a substantial portion of grains of the first region have a size within a first range of grain sizes; wherein a second metal substantially fills a second region of the through-hole located between a top surface of the first metal and the top surface of the layer of glass, wherein the second metal substantially fills a third region of the through-hole located between the bottom surface of the first metal and the bottom surface of the layer of glass, wherein a substantial portion of grains of the second region and the third region are within a second range of grain sizes, wherein a lower end of the first range of grain sizes is greater than a higher end of the second range of grain sizes; and an integrated circuit component located on the top surface of the layer of glass, a conductive contact of the integrated circuit component electrically coupled to the first region.

Example A39 includes the device of Example A38, wherein the first range of grain sizes covers grains is about one micron to ten microns and the second range of grain sizes is about less than one micron.

Example A40 includes the device of Example A38 or A39, wherein the second metal comprises is copper, nickel, palladium, or gold.

Example A41 includes the device of any one of Examples A38-A40, wherein the layer of glass comprises: silicon; oxygen; and one or more of aluminum, boron, magnesium, calcium, barium, tin, sodium, potassium, strontium, phosphorous, zirconium, lithium, titanium, and zinc.

Example A42 includes the device of any one of Examples A38-A40, wherein the layer of glass comprises aluminosilicate glass, borosilicate glass, alumino-borosilicate glass, silica, or fused silica.

Example A43 includes the device of any one of Examples A38-A40, wherein the layer of glass comprises at least 23 percent silicon by weight, at least 26 percent oxygen by weight, and further comprises at least 5 percent aluminum by weight.

Example A44 includes the device of any one of Examples A38-A43, wherein the layer of glass is amorphous.

Example A45 includes the device of any one of Examples A38-A44, wherein the layer of glass is a solid glass layer and has a rectangular shape in plan view.

Example A45 includes the device of any one of Examples A38-A44, wherein the layer of glass comprises silicon, oxygen, and aluminum.

Example A46 includes the device of any one of Examples A38-A45, wherein the integrated circuit component is a first integrated circuit component, the device further comprising a second integrated circuit component located on the bottom surface of the layer of glass, the second integrated circuit component electrically coupled to the first region.

Example A47 includes the device of any one of Examples A38-A46, further comprising a printed circuit board, the layer of glass located on the printed circuit board, a conductive contact of the printed circuit board electrically coupled to the first region.

Example A48 includes the device of Example A47 wherein the device further comprises a battery and/or an antenna located on the printed circuit board.

Example A49 is a method comprising: forming a structure, comprising: forming a through-hole in a layer of glass, wherein the through-hole extends from a top surface of the layer of glass to a bottom surface of the layer of glass; forming a seed layer on a sidewall of the through-hole, the top surface of the layer of glass, and the bottom surface of the layer of glass; and plating the seed layer with a first metal, wherein the through-hole is substantially filled with the first metal as a result of plating and a substantial portion of grains of the first metal have a size within a first range of sizes; etching and planarizing the structure, wherein, etching and planarizing leaves a first region of the first metal that substantially fills the through-hole, a first recess in the through-hole at the top surface of the first region, and a second recess in the through-hole at the bottom surface of the first region; substantially filling the first recess with a first layer comprising tin; and substantially filling the second recess with a second layer comprising tin.

Example A50 includes the method of Example A49, wherein the first layer and the second layer further comprise silver, copper, nickel, antimony, indium, palladium, or bismuth.

Example A51 includes the method of Example A49, wherein the first layer and the second layer comprise a tin-based paste.

Example A52 includes the method of any one of Examples A49-A51, wherein the layer of glass comprises silicon, oxygen, and one or more of aluminum, boron, magnesium, calcium, barium, tin, sodium, potassium, strontium, phosphorous, zirconium, lithium, titanium, and zinc.

Example A53 includes the method of any one of Examples A49-A51, wherein the layer of glass comprises aluminosilicate glass, borosilicate glass, alumino-borosilicate glass, silica, or fused silica.

Example A54 includes the method of any one of Examples A49-A51, wherein the layer of glass comprises at least 23 percent silicon by weight, at least 26 percent oxygen by weight, and further comprises at least 5 percent aluminum by weight.

Example A55 includes the method of any one of Examples A49-A51, wherein the layer of glass does not include an organic adhesive or an organic material.

Example A56 includes the method of any one of Examples A49-A55, wherein the layer of glass is amorphous.

Example A56.1 includes the method of any one of Examples A49-A55, wherein the layer of glass is solid and has a rectangular shape in plan view.

Example A57 is a method comprising: forming a structure, comprising: forming a through-hole in a layer of glass comprising silicon, oxygen, and aluminum, wherein the through-hole extends from a top surface of the layer of glass to a bottom surface of the layer of glass; forming a seed layer on a sidewall of the through-hole, the top surface of the layer of glass, and the bottom surface of the layer of glass; and plating the seed layer with a first metal, wherein the through-hole is substantially filled with the first metal as a result of plating and a substantial portion of grains of the first metal have a size within a first range of grain sizes; etching and planarizing the structure, wherein, etching and planarizing leaves a first region of the first metal that substantially fills the through-hole, a first recess in the through-hole at the top surface of the first region, and a second recess in the through-hole at the bottom surface of the first region, wherein a substantial portion of grains of the first recess and the second recess have a size within a second range of grain sizes; substantially filling, via electroless plating, the first recess with a second metal; and substantially filling, via electroless plating, the second recess with a second metal.

Example A58 includes the method of Example A57, wherein, as a result of etching and planarizing, a top end of the seed layer is substantially coincident with a top surface of the first region and a bottom end of the seed layer is substantially coincident with a bottom surface of the first region.

Example A59 includes the method of any one of Examples A57-A58 wherein the first range of grain sizes is about one micron to ten microns and the second range of grain sizes covers grain size is less than about one micron.

Example A60 includes the method of Example A57-A59, wherein the second metal comprises is copper.

Example A61 includes the method of Example A57-A59, wherein the second metal comprises is nickel, palladium, gold, or silver.

Example A62 includes the method of any one of Examples A57-A59, wherein the layer of glass comprises at least 23 percent silicon by weight, at least 26 percent oxygen by weight, and further comprises at least 5 percent aluminum by weight.

Example A63 includes the method of any one of Examples A57-A62, wherein the layer of glass does not include an organic adhesive or an organic material.

Example A64 includes the method of any one of Examples A57-A63, wherein the layer of glass is amorphous.

Example A64 includes the method of any one of Examples A57-A63, wherein the layer of glass comprises silicon, oxygen, and aluminum.

Example A65 includes the method of any one of Examples A49-A64, where the first metal is copper.

Example A66 includes the method of any one of Examples A49-A64, where the first metal is nickel, tungsten, molybdenum, platinum, gold, silver, or aluminum.

Example A67 includes the method of any one of Examples A49-A66, wherein forming the seed layer comprising: forming a third layer comprising a third metal, the third layer located on a sidewall of the through-hole, a top end of the third layer substantially coincident with the top surface of the first region, a bottom end of the third layer substantially coincident with the bottom surface of the first region; and forming a fourth layer comprising a fourth metal, the fourth layer located on the third layer and between the third layer and the first region, a top end of the fourth layer substantially coincident with the top surface of the first region, a bottom end of the fourth layer substantially coincident with the bottom surface of the first region.

Example A68 includes the method of Example A67, wherein the fourth layer comprises titanium and the third layer comprises copper.

Example A69 includes the method of Example A67, wherein the fourth layer comprises titanium and the third layer comprises silver or gold.

Example A70 is an apparatus comprising: a layer of glass; a through-hole extending from a top surface of the layer of glass to a bottom surface of the layer of glass; wherein a first metal substantially fills a first region of the through-hole to within a first distance from the top surface of the layer of glass; and a first stress relieving means to reduce stress in the layer of glass where the layer of glass meets a top surface of the first region.

Example A71 includes the apparatus of Example A70, wherein the layer of glass comprises aluminosilicate glass, borosilicate glass, alumino-borosilicate glass, silica, or fused silica.

Example A72 includes the apparatus of Example A70, wherein the layer of glass comprises at least 23 percent silicon by weight, at least 26 percent oxygen by weight, and further comprises at least 5 percent aluminum by weight.

Example A73 includes the apparatus of Example A70, wherein the layer of glass does not include an organic adhesive or an organic material.

Example A74 includes the apparatus of any one of Examples A70-A73, wherein the layer of glass is amorphous.

Example A75 includes the apparatus of Example A70-A74, wherein the layer of glass is solid and has a rectangular shape in plan view.

Example A76 includes the apparatus or device of any one of Examples A1-A48, wherein the layer of glass has a thickness in a range of about 50 microns to about 1.4 millimeters, a first length in a range of about 10 millimeters to about 250 millimeters, and a second length in a range of about 10 millimeters to about 250 millimeters, the first length perpendicular to the second length.

Example A77 includes the apparatus or device any one of Examples A1-A48, wherein the layer of glass comprises a rectangular prism volume.

Example A78 includes the apparatus or device any one of Examples A1-A48, wherein the layer of glass comprises a rectangular prism volume having a first side and a second side perpendicular to the first side, the first side having a length in a range of 10 millimeters to about 250 millimeters and the second side having a length in a range of about 10 millimeters to about 250 millimeters.

Example B1 is an apparatus, comprising: a layer of glass; and a through-hole extending from a top surface of the layer of glass to a bottom surface of the layer of glass; wherein a first metal substantially fills a first region of the through-hole; wherein a second region of the through-hole comprises a dielectric material, wherein a top surface of the first region of the through-hole has a first perimeter and the through-hole has a second perimeter at the top surface of the layer of glass, the second region of the through-hole having a top surface located between the first perimeter of the first region of the through-hole, the second region of the through-hole extending into the through-hole a maximum distance of less than 10% of a height of the glass layer; wherein a third region of the through-hole comprises the dielectric material, wherein a bottom surface of the first region of the through-hole has a third perimeter and the through-hole has a fourth perimeter at the bottom surface of the layer of glass, the third region of the through-hole having a bottom surface located between the third perimeter of the first region of the through-hole and fourth perimeter, the third region extending into the through-hole a maximum distance of less than 10% of the height of the glass layer.

Example B2 includes the apparatus of Example B1, wherein the second region of the through-hole and the third region of the through-hole have an annular or rounded rectangular shape in plan view.

Example B3 includes the apparatus of Example B1 or B2, wherein a first thickness of the second region of the through-hole at an inner perimeter of the second region of the through-hole is greater than a second thickness of the second region of the through-hole at an outer perimeter of the second region of the through-hole.

Example B4 includes the apparatus of any one of Examples B1-B3, wherein the second region of the through-hole and the third region of the through-hole have a substantially triangular cross-sectional shape.

Example B5 includes the apparatus of any one of Examples B1-B3, wherein the second region of the through-hole and the third region of the through-hole have a substantially quarter-circle cross-sectional shape.

Example B6 includes the apparatus of any one of Examples B1-B5, wherein the layer of glass comprises: silicon; oxygen; and one or more of aluminum, boron, magnesium, calcium, barium, tin, sodium, potassium, strontium, phosphorous, zirconium, lithium, titanium, and zinc.

Example B7 includes the apparatus of any one of Examples B1-B5, wherein the layer of glass comprises aluminosilicate glass, borosilicate glass, alumino-borosilicate glass, silica, or fused silica.

Example B8 includes the apparatus of any one of Examples B1-B5, wherein the layer of glass comprises at least 23 percent silicon by weight, at least 26 percent oxygen by weight, and further comprises at least 5 percent aluminum by weight.

Example B9 includes the apparatus of any one of Examples B1-B8, wherein the layer of glass does not include an organic adhesive or an organic material.

Example B10 includes the apparatus of any one of Examples B1-B9, wherein the layer of glass is amorphous.

Example B11 includes the apparatus of any one of Examples B1-B10, wherein the dielectric material is a first dielectric material, the apparatus further comprising: a first layer comprising silicon and nitrogen, the first layer located on the top surface of the layer of glass, the first layer comprising a first opening over the first region; and a second layer comprising a second dielectric material, the second layer located on the first layer, wherein the second layer comprises a second opening over the first region.

Example B12 includes the apparatus of Example B11, wherein the second dielectric material comprises carbon and nitrogen.

Example B13 includes the apparatus of Example B11, wherein the second dielectric material comprises polymers comprising carbon and oxygen.

Example B14 includes the apparatus of Example B13, wherein the second dielectric material further comprises silicon.

Example B15 includes the apparatus of any one of Examples B11-B14, further comprising a third layer comprising a second metal, the third layer substantially filling the first opening and the second opening.

Example B16 includes the apparatus of any one of Examples B1-B10, further comprising: a first layer located on a sidewall of the through-hole, the first layer comprising a second metal; and a second layer comprising a third metal, the first layer located between sidewall and the second layer, the second layer located between the first layer and the first region.

Example B16.1 includes the apparatus of any one of Examples B1-B10, wherein the layer of glass is solid and has a rectangular shape in plan view.

Example B17 is an apparatus, comprising: a layer of glass; a through-hole extending from a top surface of the layer of glass to a bottom surface of the layer of glass; wherein a first region of the through-hole comprises a first metal, wherein the first region of the through-hole substantially fills the through-hole, wherein a first metal substantially fills a first region of the through-hole; a first layer comprising a dielectric material, wherein the first layer is located on the top surface of the layer of glass, wherein the first layer comprises a first opening through which the first region of the through-hole extends, wherein the first layer comprises a first overhang that extends past a sidewall of the through-hole, wherein the first overhang comprises a first overhang portion that extends into the through-hole; and a second layer comprising the dielectric material, wherein the second layer is located on the bottom surface of the layer of glass, wherein the second layer comprises a second opening through which the first region of the through-hole extends, wherein the second layer comprises a second overhang that extends past the sidewall of the through-hole, wherein the second overhang comprises a second overhang portion that extends into the through-hole.

Example B18 includes the apparatus of Example B17, wherein the first overhang portion and the second overhang portion have a substantially triangular cross-sectional shape.

Example B19 includes the apparatus of Example B17, wherein the first overhang portion and the second overhang portion have a substantially quarter-circle cross-sectional shape.

Example B20 includes the apparatus of any one of Examples B17-B19, wherein the first overhang portion extends a first distance downwards into the through-hole at an inner perimeter of the first overhang portion and the first overhang portion extends a second distance downwards into the through-hole at an outer perimeter of the first overhang portion, the first distance greater than the second distance.

Example B21 includes the apparatus of any one of Examples B17-B20, wherein the dielectric material comprises polymers comprising carbon and oxygen.

Example B22 includes the apparatus of any one of Examples B21, wherein the dielectric material further comprises silicon.

Example B23 includes the apparatus of any one of Examples B17-B21, wherein the dielectric material comprises carbon and nitrogen.

Example B24 includes the apparatus of any one of Examples B17-B23, wherein the layer of glass comprises at least 23 percent silicon by weight, at least 26 percent oxygen by weight, and further comprises at least 5 percent aluminum by weight.

Example B25 includes the apparatus of any one of Examples B17-B24, wherein the layer of glass does not include an organic adhesive or an organic material.

Example B26 includes the apparatus of any one of Examples B17-B25, wherein the layer of glass is amorphous.

Example B27 includes the apparatus of any one of Examples B17-B26, wherein the layer of glass is a solid glass layer and has a rectangular shape in plan view.

Example B27.1 includes the apparatus of any one of Examples B17-B26, wherein the layer of glass comprises silicon, oxygen, and aluminum.

Example B28 includes the apparatus of any one of Examples B17-B27, further comprising: a third layer comprising silicon and nitrogen located between the first layer and the top surface of the layer of glass; and a fourth layer comprising silicon and nitrogen located between the second layer and the bottom surface of the layer of glass.

Example B29 includes the apparatus of Example B28, further comprising a fifth layer comprising a second metal, the third layer substantially filling the first opening.

Example B30 includes the apparatus of Examples B16 or B29, wherein the second metal is copper.

Example B31 includes the apparatus of Examples B16 or B29, wherein the second metal is silver, gold, nickel, tungsten, cobalt, or aluminum.

Example B32 includes the apparatus of any one of Examples B1-B31, where the first metal comprises copper.

Example B33 includes the apparatus of any one of Examples B1-B32, where the first metal comprises nickel, tungsten, molybdenum, platinum, gold, silver, or aluminum.

Example B34 includes the apparatus of any one of Examples B17-B33, further comprising: a first layer located on the sidewall of the through-hole, the first layer comprising a second metal; and a second layer comprising a third metal, the first layer located between the sidewall and the second layer, the second layer located between the first layer and the first region.

Example B35 includes the apparatus of Example B16 or B34, wherein the first layer comprises titanium and the second layer comprises copper.

Example B36 includes the apparatus of Example B34, wherein a top portion of the first layer is positioned between the first overhang portion and the layer of glass and a bottom portion of the first layer is positioned between the second overhang portion and the layer of glass.

Example B37 includes the apparatus of Example B16 or B34, wherein the second layer comprises titanium and the third layer comprises silver.

Example B38 includes the apparatus of Example B16 or B34, wherein the second layer comprises titanium and the third layer comprises gold.

Example B39. A device, comprising: a layer of glass; and a through-hole extending from a top surface of the layer of glass to a bottom surface of the layer of glass; wherein a first metal substantially fills a first region of the through-hole; wherein a second region of the through-hole comprises a dielectric material, wherein a top surface of the first region of the through-hole has a first perimeter and the through-hole has a second perimeter at the top surface of the layer of glass, the second region of the through-hole having a top surface located between the first perimeter of the first region of the through-hole, the second region of the through-hole extending into the through-hole a maximum distance of less than 30% of a height of the glass layer; wherein a third region of the through-hole comprises the dielectric material, wherein a bottom surface of the first region of the through-hole has a third perimeter and the through-hole has a fourth perimeter at the bottom surface of the layer of glass, the third region of the through-hole having a bottom surface located between the third perimeter of the first region of the through-hole and fourth perimeter, the third region extending into the through-hole a maximum distance of less than 30% of the height of the glass layer ; and an integrated circuit component located on the top surface of the layer of glass, a conductive contact of the integrated circuit component electrically coupled to the first region.

Example B40 includes the device of Example B39, wherein the second region of the through-hole and the third region of the through-hole have an annular or rounded rectangular shape in plan view.

Example B41 includes the device of Example B39 or B40, wherein a first thickness of the second region of the through-hole at an inner perimeter of the second region of the through-hole is greater than a second thickness of the second region of the through-hole at an outer perimeter of the second region of the through-hole.

Example B42 includes the device of any one of Examples B39-B41, wherein the second region and the third region have a substantially triangular cross-sectional shape.

Example B43 includes the device of any one of Examples B39-B41, wherein the second region and the third region have a substantially quarter-circle cross-sectional shape.

Example B44 includes the device of any one of Examples B39-B43, wherein the layer of glass comprises: silicon; oxygen; and one or more of aluminum, boron, magnesium, calcium, barium, tin, sodium, potassium, strontium, phosphorous, zirconium, lithium, titanium, and zinc.

Example B45 includes the device of any one of Examples B39-B43, wherein the layer of glass comprises aluminosilicate glass, borosilicate glass, alumino-borosilicate glass, silica, or fused silica.

Example B46 includes the device of any one of Examples B39-B43, wherein the layer of glass comprises at least 23 percent silicon by weight, at least 26 percent oxygen by weight, and further comprises at least 5 percent aluminum by weight.

Example B47 includes the device of any one of Examples B39-B46, wherein the layer of glass does not include an organic adhesive or an organic material.

Example B48 includes the device of any one of Examples B39-B47, wherein the layer of glass is amorphous.

Example B49 includes the device of any one of Examples B39-B48, wherein the layer of glass is a solid glass layer and has a rectangular shape in plan view.

Example B49.1 includes the device of any one of Examples B39-B48, wherein the layer of glass comprises at least 23 percent silicon by weight, at least 26 percent oxygen by weight, and further comprises at least 5 percent aluminum by weight.

Example B50 includes the device of any one of Examples B39-B49, wherein the dielectric material is a first dielectric material, the device further comprising: a first layer comprising silicon and nitrogen, the first layer located on the top surface of the layer of glass, the first layer comprising a first opening over the first region; and a second layer comprising a second dielectric material, the second layer located on the first layer, wherein the second layer comprises a second opening over the first region.

Example B51 includes the device of Example B50, wherein the second dielectric material comprises carbon and nitrogen.

Example B52 includes the device of Example B50, wherein the second dielectric material comprises polymers comprising carbon and oxygen.

Example B53 includes the device of Example B52, wherein the second dielectric material further comprises silicon.

Example B54 includes the device of any one of Examples B50-B53, further comprising a third layer comprising a second metal, the third layer substantially filling the first opening and the second opening.

Example B55 includes the device of any one of Examples B39-B54, further comprising: a first layer located on a sidewall of the through-hole, the first layer comprising a second metal; and a second layer comprising a third metal, the first layer located between sidewall and the second layer, the second layer located between the first layer and the first region.

Example B56. A device, comprising: a layer of glass; a through-hole extending from a top surface of the layer of glass to a bottom surface of the layer of glass; wherein a first region of the through-hole comprises a first metal, wherein the first region of the through-hole substantially fills the through-hole, wherein a first metal substantially fills a first region of the through-hole; a first layer comprising a dielectric material, wherein the first layer is located on the top surface of the layer of glass, wherein the first layer comprises a first opening through which the first region of the through-hole extends, wherein the first layer comprises a first overhang that extends past a sidewall of the through-hole, wherein the first overhang comprises a first overhang portion that extends into the through-hole; a second layer comprising the dielectric material, wherein the second layer is located on the bottom surface of the layer of glass, wherein the second layer comprises a second opening through which the first region of the through-hole extends, wherein the second layer comprises a second overhang that extends past the sidewall of the through-hole, wherein the second overhang comprises a second overhang portion that extends into the through-hole; and an integrated circuit component located on the top surface of the layer of glass, a conductive contact of the integrated circuit component electrically coupled to the first region.

Example B57 includes the device of Example B56, wherein the first overhang portion and the second overhang portion have a substantially triangular cross-sectional shape.

Example B58 includes the device of Example B56, wherein the first overhang portion and the second overhang portion have a substantially quarter-circle cross-sectional shape.

Example B59 includes the device of any one of Examples B56-B58, wherein the first overhang portion extends a first distance downwards into the through-hole at an inner perimeter of the first overhang portion and the first overhang portion extends a second distance downwards into the through-hole at an outer perimeter of the first overhang portion, the first distance greater than the second distance.

Example B60 includes the device of any one of Examples B56-B59, wherein the dielectric material comprises polymers comprising carbon and oxygen.

Example B61 includes the device of any one of Examples B60, wherein the dielectric material further comprises silicon.

Example B62 includes the device of any one of Examples B56-B60, wherein the dielectric material comprises carbon and nitrogen.

Example B63 includes the device of any one of Examples B56-B62, wherein the layer of glass comprises at least 23 percent silicon by weight, at least 26 percent oxygen by weight, and further comprises at least 5 percent aluminum by weight.

Example B64 includes the device of any one of Examples B56-B63, wherein the layer of glass does not include an organic adhesive or an organic material.

Example B65 includes the device of any one of Examples B56-B64, wherein the layer of glass is amorphous.

Example B66.1 includes the device of any one of Examples B56-B65, wherein the layer of glass comprises silicon, oxygen, and aluminum.

Example B66 includes the device of any one of Examples B56-B65, wherein the layer of glass is a solid glass layer and has a rectangular shape in plan view.

Example B67 includes the device of any one of Examples B56-B66, further comprising: a third layer comprising silicon and nitrogen located between the first layer and the top surface of the layer of glass; and a fourth layer comprising silicon and nitrogen located between the second layer and the bottom surface of the layer of glass.

Example B68 includes the device of Example B67, further comprising a fifth layer comprising a second metal, the third layer substantially filling the first opening.

Example B69 includes the device of Examples B54 or B68, wherein the second metal is copper.

Example B70 includes the device of Examples B54 or B68, wherein the second metal is silver, gold, nickel, tungsten, cobalt, or aluminum.

Example B71 includes the device of any one of Examples B39-B70, where the first metal comprises copper.

Example B72 includes the device of any one of Examples B39-B70, where the first metal comprises nickel, tungsten, molybdenum, platinum, gold, silver, or aluminum.

Example B73 includes the device of any one of Examples B56-B72, further comprising: a first layer located on a sidewall of the through-hole, the first layer comprising a second metal; and a second layer comprising a third metal, the first layer located between sidewall and the second layer, the second layer located between the first layer and the first region.

Example B74 includes the device of Example B55 or B73, wherein the first layer comprises titanium and the second layer comprises copper.

Example B75 includes the device of Example B73, wherein a top portion of the first layer is positioned between the first overhang portion and the layer of glass and a bottom portion of the first layer is positioned between the second overhang portion and the layer of glass.

Example B76 includes the device of Example B55 or B73, wherein the second layer comprises titanium and the third layer comprises silver.

Example B77 includes the device of Example B55 or B73, wherein the second layer comprises titanium and the third layer comprises gold.

Example B78. A method comprising: forming a structure, comprising: forming a through-hole in a layer of glass, wherein the through-hole extends from a top surface of the layer of glass to a bottom surface of the layer of glass; forming an adhesion promotion layer on a sidewall of the through-hole, the top surface of the layer of glass, and the bottom surface of the layer of glass; forming a dielectric layer on the top surface of the layer of glass, a portion of the dielectric layer extending into the through-hole; forming a hole in the dielectric layer, the hole positioned over the through-hole; forming a seed layer on the adhesion promotion seed layer in the through-hole; and plating the seed layer with a metal, wherein the through-hole is substantially filled with the metal as a result of the plating; and etching and planarizing the structure, wherein etching and planarizing leaves a region of the metal that substantially fills the through-hole, and leaves a portion of the dielectric layer in the through-hole, wherein a top surface of the region of the metal has a first perimeter and the through-hole has a second perimeter at the top surface of the layer of glass, the portion of the dielectric layer in the through-hole having a top surface located between the first perimeter and the second perimeter, the portion of the dielectric layer in the through-hole extending into the through-hole a maximum distance of less than 10% of a height of the layer of glass.

Example B79 includes the method of Example B78, wherein the portion of the dielectric layer in the through-hole has an annular or rounded rectangular shape in plan view.

Example B80 includes the method of Example B78 or B79, wherein a first thickness of the portion of the dielectric layer in the through-hole at an inner perimeter of the portion of the dielectric layer in the through-hole is greater than a second thickness of the portion of the dielectric layer in the through-hole at an outer perimeter of the portion of the dielectric layer in the through-hole.

Example B81 includes the method of any one of Examples B78-B80, wherein the portion of the dielectric layer in the through-hole has a substantially quarter-circle cross-sectional shape.

Example B82. A method comprising: forming a through-hole in a layer of glass, and wherein the through-hole extends from a top surface of the layer of glass to a bottom surface of the layer of glass; forming an adhesion promotion layer on a sidewall of the through-hole, the top surface of the layer of glass, and the bottom surface of the layer of glass; forming a dielectric layer on the top surface of the layer of glass, a portion of the dielectric layer extending into the through-hole, the dielectric layer comprising a dielectric material; forming an opening in the dielectric layer, the opening positioned over the through-hole, the dielectric layer comprising, as a result of forming the opening in the dielectric layer, an overhang that extends past a sidewall of the through-hole, wherein the overhang comprises an overhang portion that extends into the through-hole; forming a seed layer on the adhesion promotion layer in the through-hole; and plating the seed layer with a metal, wherein the through-hole is substantially filled with the metal as a result of plating.

Example B83 includes the method of Example B82, wherein the overhang portion has a substantially triangular cross-sectional shape.

Example B84 includes the method of Example B82, wherein the overhang portion has a substantially quarter-circle cross-sectional shape.

Example B85 includes the method of any one of Examples B82-B84, wherein the overhang portion extends a first distance downwards into the through-hole at an inner perimeter of the overhang portion and the overhang portion extends a second distance downwards into the through-hole at an outer perimeter of the overhang portion, the first distance greater than the second distance.

Example B86 includes the method of any one of Examples B82-B85, wherein the dielectric material comprises polymers comprising carbon and oxygen.

Example B87 includes the method of any one of Examples B86, wherein the dielectric material further comprises silicon.

Example B88 includes the method of any one of Examples B82-B87, wherein the dielectric material comprises carbon and nitrogen.

Example B89 includes the method of any one of Examples B78-B88, wherein the layer of glass comprises: silicon; oxygen; and one or more of aluminum, boron, magnesium, calcium, barium, tin, sodium, potassium, strontium, phosphorous, zirconium, lithium, titanium, and zinc.

Example B90 includes the method of any one of Examples B78-B88, wherein the layer of glass comprises aluminosilicate glass, borosilicate glass, alumino-borosilicate glass, silica, or fused silica.

Example B91 includes the method of any one of Examples B78-B88, wherein the layer of glass comprises at least 23 percent silicon by weight, at least 26 percent oxygen by weight, and further comprises at least 5 percent aluminum by weight.

Example B92 includes the method of any one of Examples B78-B91, wherein the layer of glass does not include an organic adhesive or an organic material.

Example B93 includes the method of any one of Examples B78-B92, wherein the layer of glass is amorphous.

Example B93.1 includes the method of any one of Examples B78-B92, wherein the layer of glass is solid and has a rectangular shape in plan view.

Example B94 includes the method of any one of Examples B78-B93, further comprising attaching an integrated circuit component to the structure.

Example B95 includes the apparatus or device of any one of Examples B1-B77, wherein the layer of glass has a thickness in a range of about 50 microns to about 1.4 millimeters, a first length in a range of about 10 millimeters to about 250 millimeters, and a second length in a range of about 10 millimeters to about 250 millimeters, the first length perpendicular to the second length.

Example B96 includes the apparatus or device any one of Examples B1-B77, wherein the layer of glass comprises a rectangular prism volume.

Example B97 includes the apparatus or device any one of Examples B1-B77, wherein the layer of glass comprises a rectangular prism volume having a first side and a second side perpendicular to the first side, the first side having a length in a range of 10 millimeters to about 250 millimeters and the second side having a length in a range of about 10 millimeters to about 250 millimeters.

1. An apparatus, comprising:
a layer of glass; and
a through-hole extending from a top surface of the layer of glass to a bottom surface of the layer of glass, wherein a first metal substantially fills a first region of the through-hole to within a first distance from the top surface of the layer of glass and to within a second distance from the bottom surface of the layer of glass, wherein a second metal substantially fills a second region of the through-hole located between a top surface of the first region and the top surface of the layer of glass, and wherein the second metal substantially fills a third region of the through-hole located between the bottom surface of the first region and the bottom surface of the layer of glass.

2. The apparatus of claim 1, wherein the second metal is tin.

3. The apparatus of claim 1, wherein the second region and the third region further comprise silver, copper, nickel, antimony, indium, palladium, or bismuth.

4. The apparatus of claim 1, wherein the second region and the third region comprise a paste comprising the second metal.

5. The apparatus of claim 1, where the first metal is copper, nickel, tungsten, molybdenum, platinum, gold, silver, or aluminum.

6. The apparatus of claim 1, further comprising:
a first layer comprising a third metal, the first layer located on a sidewall of the through-hole, a top end of the first layer substantially coincident with the top surface of the first region, a bottom end of the first layer substantially coincident with the bottom surface of the first region; and
a second layer comprising a fourth metal, the second layer located on the first layer and between the first layer and the first region, a top end of the second layer substantially coincident with the top surface of the first region, a bottom end of the second layer substantially coincident with the bottom surface of the first region.

7. The apparatus of claim 6, wherein the first layer comprises titanium and the second layer comprises copper, silver, or gold.

8. An apparatus, comprising:
a layer of glass comprising silicon, oxygen, and aluminum; and
a through-hole extending from a top surface of the layer of glass to a bottom surface of the layer of glass, wherein a first metal substantially fills a first region of the through-hole to within a first distance from the top surface of the layer of glass and to within a second distance from the bottom surface of the layer of glass, wherein a substantial portion of grains of the first region have a size within a first range of grain sizes; wherein a second metal substantially fills a second region of the through-hole located between a top surface of the first metal and the top surface of the layer of glass, wherein the second metal substantially fills a third region of the through-hole located between the bottom surface of the first metal and the bottom surface of the layer of glass, wherein a substantial portion of grains of the second region and the third region are within a second range of grain sizes, wherein a lower end of the first range of grain sizes is greater than a higher end of the second range of grain sizes.

9. The apparatus of claim 8 wherein the first range of grain sizes is about one micron to ten microns and the second range of grain sizes is less than about one micron.

10. The apparatus of claim 8, wherein the second metal comprises is copper.

11. The apparatus of claim 8, wherein the second metal comprises is nickel, palladium, gold, or silver.

12. The apparatus of claim 8, where the first metal is copper, nickel, tungsten, molybdenum, platinum, gold, silver, or aluminum.

13. The apparatus of claim 8, further comprising:
a first layer comprising a third metal, the first layer located on a sidewall of the through-hole, a top end of the first layer substantially coincident with the top surface of the first region, a bottom end of the first layer substantially coincident with the bottom surface of the first region; and
a second layer comprising a fourth metal, the second layer located on the first layer and between the first layer and the first region, a top end of the second layer substantially coincident with the top surface of the first region, a bottom end of the second layer substantially coincident with the bottom surface of the first region.

14. The apparatus of claim 13, wherein the first layer comprises titanium and the second layer comprises copper, silver, or gold.

15. A device comprising:
a layer of glass;
a through-hole extending from a top surface of the layer of glass to a bottom surface of the layer of glass, wherein a first metal substantially fills a first region of the through-hole to within a first distance from the top surface of the layer of glass and to within a second distance from the bottom surface of the layer of glass, wherein a second metal substantially fills a second region of the through-hole located between a top surface of the first region and the top surface of the layer of glass, and wherein the second metal substantially fills a third region of the through-hole located between the bottom surface of the first region and the bottom surface of the layer of glass; and
an integrated circuit component located on the top surface of the layer of glass, a conductive contact of the integrated circuit component electrically coupled to the first region.

16. The device of claim 15, wherein the second metal is tin.

17. The device of claim 15, wherein the second region and the third region further comprise silver, copper, nickel, antimony, indium, palladium, or bismuth.

18. The device of claim 15, wherein the integrated circuit component is a first integrated circuit component, the device further comprising a second integrated circuit component located on the bottom surface of the layer of glass, the second integrated circuit component electrically coupled to the first region.

19. The device of claim 15, further comprising a printed circuit board, the layer of glass located on the printed circuit board, a conductive contact of the printed circuit board electrically coupled to the first region.

20. The device of claim 19, wherein the device further comprises a battery and/or an antenna located on the printed circuit board.
